(19) United States
(12) Patent Application Publication
(10) Pub. No.: US 2024/0304680 A1
(43) Pub. Date: Sep. 12, 2024

(54) METHOD OF MANUFACTURING SEMICONDUCTOR DEVICE

(71) Applicant: Renesas Electronics Corporation, Tokyo (JP)

(72) Inventors: Takahiro MARUYAMA, Tokyo (JP); Tomoki AYANO, Tokyo (JP); Yuya ABIKO, Tokyo (JP)

(21) Appl. No.: 18/437,947

(22) Filed: Feb. 9, 2024

(30) Foreign Application Priority Data
Mar. 10, 2023 (JP) 2023-037815

(51) Int. Cl. H01L 29/40; H01L 29/423

(52) U.S. Cl. CPC H01L 29/401; H01L 29/407; H01L 29/4236

(57) ABSTRACT

A field plate electrode is formed in an inside of a trench via a first insulating film. Another part of the field plate electrode is selectively removed such that part of the field plate electrode is left as a lead portion. After the first insulating film is recessed, a protective film is formed on the first insulating film. A gate insulating film is formed in the inside of the trench, and a second insulating film is formed so as to cover the field plate electrode. A conductive film is formed on the gate insulating, second insulating film and protective films. A gate electrode is formed on the field plate electrode by removing the conductive film located in an outside of the trench. At this time, the conductive film formed on each of the protective film and the second insulating film, which are in contact with the lead portion, is removed.

### CROSS-REFERENCE TO RELATED APPLICATION

The disclosure of Japanese Patent Application No. 2023-037815 filed on Mar. 10, 2023, including the specification, drawings and abstract is incorporated herein by reference in its entirety.

### BACKGROUND

The present invention relates to a method of manufacturing a semiconductor device, and particularly relates to a method of manufacturing a semiconductor device including a gate electrode and a field plate electrode formed inside a trench.

A trench gate structure in which a gate electrode is embedded inside a trench is applied to a semiconductor device including a semiconductor element such as a power metal oxide semiconductor field effect transistor (MOSFET). One type of the trench gate structure is a split-gate structure in which a field plate electrode is formed under the trench while a gate electrode is formed above the trench. To the field plate electrode, a source potential is supplied from a source electrode. By the field plate electrode, a depletion layer is spread in a drift region, so that the drift region can have a higher concentration, and a resistance of the drift region can be decreased.

There is disclosed technique listed below.
[Patent Document 1] Japanese Unexamined Patent Application Publication No. 2011-199109

For example, the Patent Document 1 discloses the MOSFET with the split-gate structure. The field plate electrode and the gate electrode in the Patent Document 1 are formed as described below. First, the field plate electrode is formed inside the trench, and then, an upper surface of the field plate electrode is recessed. Next, a conductive film for the gate electrode is deposited on a semiconductor substrate so as to fill the inside of the trench on the field plate electrode. Next, the gate electrode is formed above the trench by anisotropic etching on the conductive film.

### SUMMARY

FIG. 50 illustrates a semiconductor device according to an examined example examined by the present inventors on the basis of the Patent Document 1 and others. A field plate electrode FP includes a lead portion FPa to be electrically connected with a source electrode. The field plate electrode FP of the lead portion FPa is formed at not only a lower portion of a trench TR1 but also an upper portion of the trench TR1.

The field plate electrode FP is formed inside the trench TR1 via a thick insulating film IF1. Next, a part of the field plate electrode FP is removed to recess the field plate electrode FP from the upper portion of the trench TR1 toward the lower portion of the trench TR1. However, another part of the field plate electrode FP is left as the lead portion FPa. Next, part of the insulating film IF1 is removed to recess the insulating film IF1 from the upper portion of the trench TR1 toward the lower portion of the trench TR1. Next, a gate insulating film GI is formed inside the trench TR1 on the insulating film IF1, and an insulating film IF2 is formed so as to cover the field plate electrode FP exposed from the insulating film IF1. Next, a conductive film CF2 for a gate electrode is deposited.

Next, an anisotropic etching process is performed to the conductive film CF2 to form the gate electrode at the upper portion of the trench TR1. At this time, a residue RS of the conductive film CF2 may be left on a side surface of the lead portion FPa. At the time of operation of the MOSFET, a source potential Vs of, for example, 0 V is supplied to the lead portion FPa, and a drain potential Vd of, for example, 100 V is supplied to a drift region NV (semiconductor substrate SUB).

Typically, dielectric breakdown between the lead portion FPa and the drift region NV is maintained by the thickness of the insulating film IF1. However, if the residue RS of an electrically floating state exists, series capacitance is configured of capacitance between the lead portion FPa and the residue RS (see FIG. 50) and capacitance between the residue RS and the drift region NV (see FIG. 50). A voltage of 100 V is applied to the series capacitance, and therefore, there is a problem of failure to maintain the dielectric breakdown between the lead portion FPa and the drift region NV.

Particularly, when the insulating film IF1 is made thick for improving the dielectric breakdown, it is necessary to lengthen time for an isotropic etching process for recessing the insulating film IF1, and therefore, the residue RS is easily formed deeper. A space between the gate insulating film GI and the insulating film IF2 is wider, and therefore, a larger residue RS is easily formed.

A main object of the present application is to suppress such formation of the residue RS to improve reliability of the semiconductor device. Other problems and novel characteristics will be apparent from the description of the present specification and the accompanying drawings.

The outline of the typical aspects of the embodiments disclosed in the present application will be briefly described as follows.

A method of manufacturing a semiconductor device according to one embodiment includes a step of (a) of preparing a semiconductor substrate of a first conductive type, the semiconductor substrate having an upper surface and a lower surface, a step of (b) of forming a trench in the semiconductor substrate to have a predetermined depth from the upper surface of the semiconductor substrate toward the lower surface of the semiconductor substrate after the step of (a), a step of (c) of forming a first insulating film on the upper surface of the semiconductor substrate and in an inside of the trench after the step of (b), a step of (d) of forming a first conductive film on the first insulating film so as to fill the inside of the trench after the step of (c), a step of (e) of forming, as a field plate electrode, the first conductive film left in the inside of the trench by removing the first conductive film located in an outside of the trench, after the step of (d), a step of (f) of selectively removing an another part of the field plate electrode such that a part of the field plate electrode is left as a lead portion after the step of (e), a step of (g) of removing the first insulating film located on the upper surface of the semiconductor substrate, and recessing the first insulating film located in the inside of the trench toward a bottom portion of the trench such that an upper surface of the first insulating film located in the inside of the trench is positioned lower than an upper surface of the field plate electrode in cross sectional view after the step of (f), a step of (h) of forming a first protective film on the upper surface of the semiconductor substrate and in the inside of the trench so as to cover the field plate electrode and the first insulating film after the step of (g), a step of (i) of removing the first protective film located on the upper surface of the semiconductor substrate, and recessing the first protective film located in the inside of the trench toward the bottom portion of the trench such that an upper surface of the first protective film is positioned lower than the upper surface of the field plate electrode after the step of (h), a step of (j) of forming a gate insulating film in the inside of the trench located on the first protective film, and forming a second insulating film so as to cover the field plate electrode exposed from the first protective film after the step of (i), a step of (k) of forming a second conductive film on each of the gate insulating film, the second insulating film and the first protective film so as to fill the inside of the trench after the step of (j), and a step of (1) of forming, as a gate electrode, the second conductive film left in the inside of the trench, which is located at a portion over on the field plate electrode, by removing the second conductive film located in the outside of the trench after the step of (k). The second conductive film formed on the first protective film and the second insulating film, which are in contact with the lead portion, in the step of (k) is removed in the step of (l).

A method of manufacturing a semiconductor device according to one embodiment includes a step of (a) of preparing a semiconductor substrate of a first conductive type, the semiconductor substrate having an upper surface and a lower surface, a step of (b) of forming a trench in the semiconductor substrate to have a predetermined depth from the upper surface of the semiconductor substrate after the step of (a), a step of (c) of forming a first insulating film on the upper surface of the semiconductor substrate and in an inside of the trench after the step of (b), a step of (d) of forming a first conductive film on the first insulating film so as to fill the inside of the trench after the step of (c), a step of (e) of forming, as a field plate electrode, the first conductive film left in the inside of the trench by removing the first conductive film located in an outside of the trench after the step of (d), a step of (f) of forming a second protective film so as to cover the field plate electrode and the first insulating film located on the upper surface of the semiconductor substrate after the step of (e), a step of (g) of forming, on the second protective film, a first resist pattern, which has a pattern covering part of the field plate electrode, and exposing an another part of the field plate electrode after the step of (f), a step of (h) of removing the second protective film formed on the another part of the field plate electrode by performing an anisotropic etching process while using the first resist pattern as a mask after the step of (g), a step of (i) of selectively recessing the another part of the field plate electrode by performing an anisotropic etching process while using the first resist pattern as a mask such that the part of the field plate electrode is left as a lead portion after the step of (h), a step of (j) of removing the first resist pattern after the step of (i), a step of (k) of removing the second protective film formed on the lead portion and the first insulating film located on the upper surface of the semiconductor substrate, and recessing the first insulating film located in the inside of the trench such that an upper surface of the first insulating film is positioned lower than an upper surface of the field plate electrode after the step of (j), a step of (l) of forming a gate insulating film in the inside of the trench located on the first insulating film, and forming a second insulating film so as to cover the field plate electrode exposed from the first insulating film after the step of (k), a step of (m) of forming a second conductive film on each of the gate insulating film, the second insulating film and the first insulating film so as to fill the inside of the trench after the step of (l), and a step of (n) of forming, as a gate electrode, the second conductive film left in the inside of the trench, which is located at a portion over the field plate electrode, by removing the second conductive film located in the outside of the trench after the step of (m). The second conductive film formed on the first insulating film and the second insulating film, which are in contact with the lead portion, in the step of (m) is removed in the step of (n).

A method of manufacturing a semiconductor device according to one embodiment includes a step of (a) of preparing a semiconductor substrate of a first conductive type, the semiconductor substrate having an upper surface and a lower surface, a step of (b) of forming a trench in the semiconductor substrate to have a predetermined depth from the upper surface of the semiconductor substrate after the step of (a), a step of (c) of forming a first insulating film on the upper surface of the semiconductor substrate and in an inside of the trench after the step of (b), a step of (d) of forming a first conductive film on the first insulating film so as to fill the inside of the trench after the step of (c), a step of (e) of forming, as a field plate electrode, the first conductive film left in the inside of the trench by removing the first conductive film located in an outside of the trench after the step of (d), a step of (f) of forming, on the upper surface of the semiconductor substrate, a mask layer which has a pattern covering part of the field plate electrode, and exposing an another part of the field plate electrode after the step of (e), a step of (g) of selectively recessing the another part of the field plate electrode while using the mask layer as a mask such that the part of the field plate electrode is left as a lead portion after the step of (f), and a step of (h) of removing the first insulating film located on the upper surface of the semiconductor substrate exposed from the mask layer, and recessing the first insulating film located in the inside of the trench such that an upper surface of the first insulating film exposed from the mask layer is positioned lower than an upper surface of the field plate electrode while using the mask layer as a mask after the step of (g).

According to one embodiment, reliability of the semiconductor device can be improved.

### BRIEF DESCRIPTIONS OF THE DRAWINGS

FIG. 1 is a plan view illustrating a semiconductor device according to a first embodiment.

FIG. 2 is a plan view of a principal part illustrating the semiconductor device according to the first embodiment.

FIG. 3 is a plan view of a principal part illustrating the semiconductor device according to the first embodiment.

FIG. 4 is a plan view illustrating layouts of a field plate electrode and a gate electrode according to the first embodiment.

FIG. 5 is a cross sectional view illustrating the semiconductor device according to the first embodiment.

FIG. 6 is a cross sectional view illustrating a step of manufacturing the semiconductor device according to the first embodiment.

FIG. 7 is a cross sectional view illustrating a manufacturing step continued from FIG. 6.

FIG. 8 is a cross sectional view illustrating a manufacturing step continued from FIG. 7.

FIG. 9 is a cross sectional view illustrating a manufacturing step continued from FIG. 8.

FIG. 10 is a cross sectional view illustrating a manufacturing step continued from FIG. 9.

FIG. 11 is a cross sectional view illustrating a manufacturing step continued from FIG. 10.

FIG. 12 is a cross sectional view illustrating a manufacturing step continued from FIG. 11.

FIG. 13 is a cross sectional view illustrating a manufacturing step continued from FIG. 12.

FIG. 14 is a cross sectional view illustrating a manufacturing step continued from FIG. 13.

FIG. 15 is a cross sectional view illustrating a manufacturing step continued from FIG. 14.

FIG. 16 is a cross sectional view illustrating a manufacturing step continued from FIG. 15.

FIG. 17 is a cross sectional view illustrating a manufacturing step continued from FIG. 16.

FIG. 18 is a cross sectional view illustrating a manufacturing step continued from FIG. 17.

FIG. 19 is a cross sectional view illustrating a manufacturing step continued from FIG. 18.

FIG. 20 is a cross sectional view illustrating a manufacturing step continued from FIG. 19.

FIG. 21 is a cross sectional view illustrating a manufacturing step continued from FIG. 20.

FIG. 22 is a cross sectional view illustrating a step of manufacturing a semiconductor device according to a second embodiment.

FIG. 23 is a cross sectional view illustrating a manufacturing step continued from FIG. 22.

FIG. 24 is a cross sectional view illustrating a manufacturing step continued from FIG. 23.

FIG. 25 is a cross sectional view illustrating a manufacturing step continued from FIG. 24.

FIG. 26 is a cross sectional view illustrating the semiconductor device according to the second embodiment.

FIG. 27 is a cross sectional view illustrating a step of manufacturing a semiconductor device according to a first examined example.

FIG. 28 is a cross sectional view illustrating the semiconductor device according to the first examined example.

FIG. 29 is a plan view of a principal part illustrating the semiconductor device according to the first examined example.

FIG. 30 is a cross sectional view illustrating a step of manufacturing a semiconductor device according to a third embodiment.

FIG. 31 is a cross sectional view illustrating a manufacturing step continued from FIG. 30.

FIG. 32 is a cross sectional view illustrating a manufacturing step continued from FIG. 31.

FIG. 33 is a cross sectional view illustrating a manufacturing step continued from FIG. 32.

FIG. 34 is a cross sectional view illustrating a manufacturing step continued from FIG. 33.

FIG. 35 is a cross sectional view illustrating a step of manufacturing a semiconductor device according to a second examined example.

FIG. 36 is a cross sectional view of a principal part illustrating details of the manufacturing step of FIG. 35.

FIG. 37 is a cross sectional view illustrating a manufacturing step continued from FIG. 35.

FIG. 38 is a cross sectional view illustrating a manufacturing step continued from FIG. 37.

FIG. 39 is a cross sectional view illustrating a manufacturing step continued from FIG. 38.

FIG. 40 is a cross sectional view illustrating a manufacturing step continued from FIG. 39.

FIG. 41 is a cross sectional view illustrating a manufacturing step continued from FIG. 40.

FIG. 42 is a cross sectional view illustrating a step of manufacturing a semiconductor device according to a fourth embodiment.

FIG. 43 is a cross sectional view illustrating a manufacturing step continued from FIG. 42.

FIG. 44 is a cross sectional view illustrating a manufacturing step continued from FIG. 43.

FIG. 45 is a cross sectional view illustrating a step of manufacturing a semiconductor device according to a third examined example.

FIG. 46 is a cross sectional view illustrating a manufacturing step continued from FIG. 45.

FIG. 47 is a cross sectional view illustrating a manufacturing step continued from FIG. 46.

FIG. 48 is a cross sectional view illustrating a manufacturing step continued from FIG. 47.

FIG. 49 is a cross sectional view illustrating a manufacturing step continued from FIG. 48.

FIG. 50 is a cross sectional view illustrating a semiconductor device according to an examined example.

### DETAILED DESCRIPTION

Hereinafter, embodiments will be described in detail with reference to the accompanying drawings. Note that components having the same function are denoted by the same reference signs throughout all the drawings for explaining the embodiments, and the repetitive description thereof will be omitted. In addition, the description of the same or similar portions is not repeated in principle unless otherwise particularly required in the following embodiments.

An X direction, a Y direction, and a Z direction described in the present application cross with one another, and are orthogonal to one another. In the present application, the Z direction will be described as a vertical direction, a height direction, or a thickness direction of a structure. The expressions such as “plan view” or “planar view” used in the present application mean that a “plane” made of the X direction and the Y direction is viewed in the Z direction.

### First Embodiment

### <Structure of Semiconductor Device>

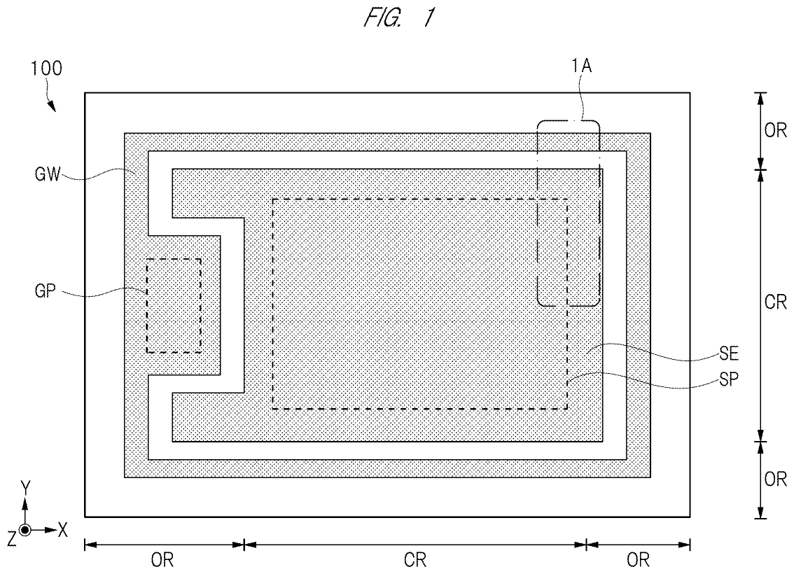

A semiconductor device 100 according to a first embodiment will be described below with reference to FIGS. 1 to 5. The semiconductor device 100 includes a MOSFET of a trench gate structure as a semiconductor element. The MOSFET of the first embodiment has a split gate structure including a gate electrode GE and a field plate electrode FP.

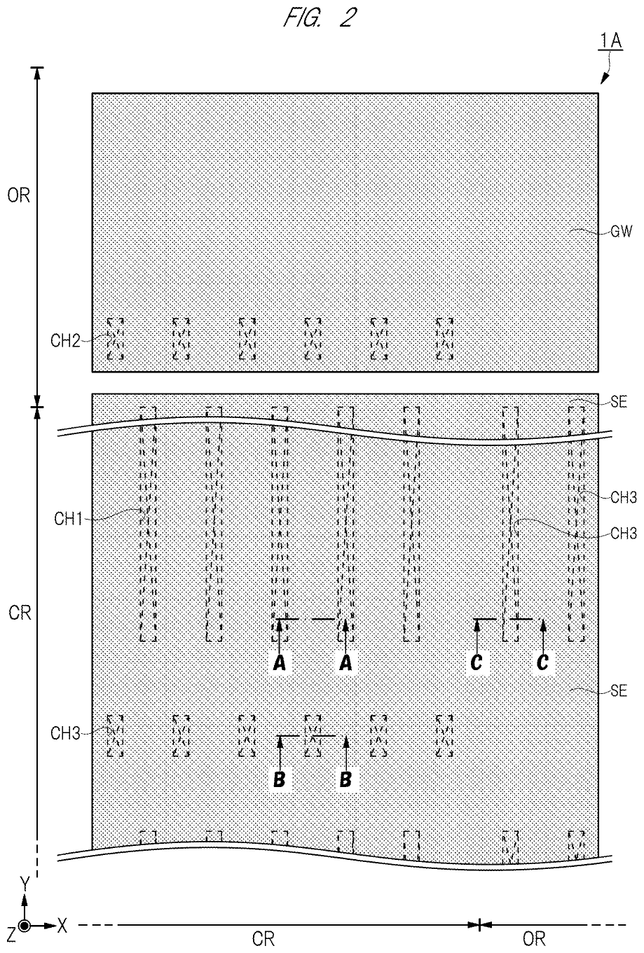

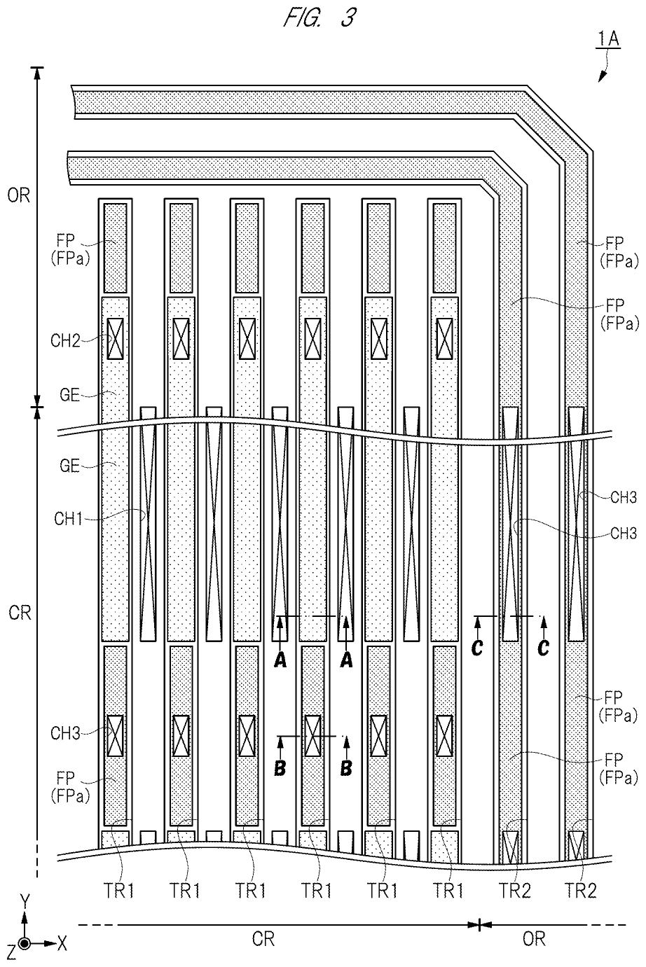

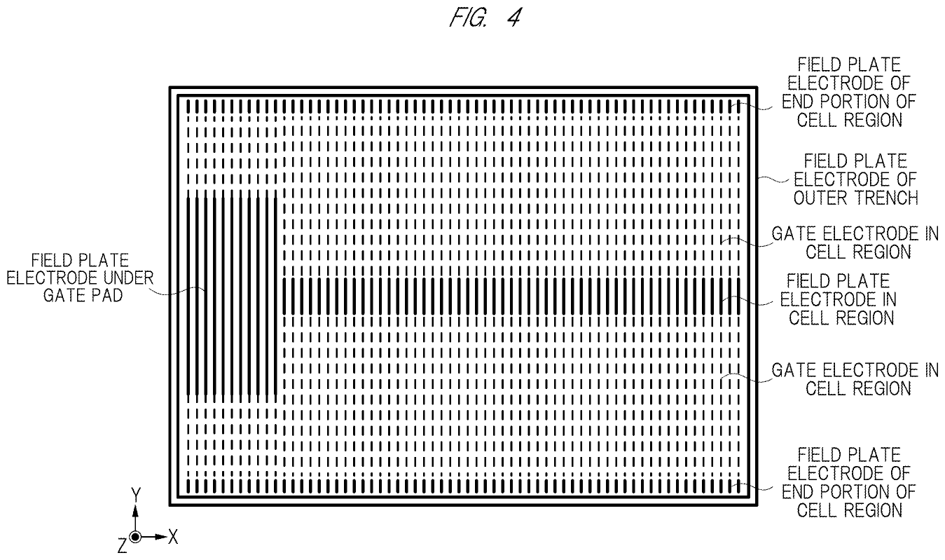

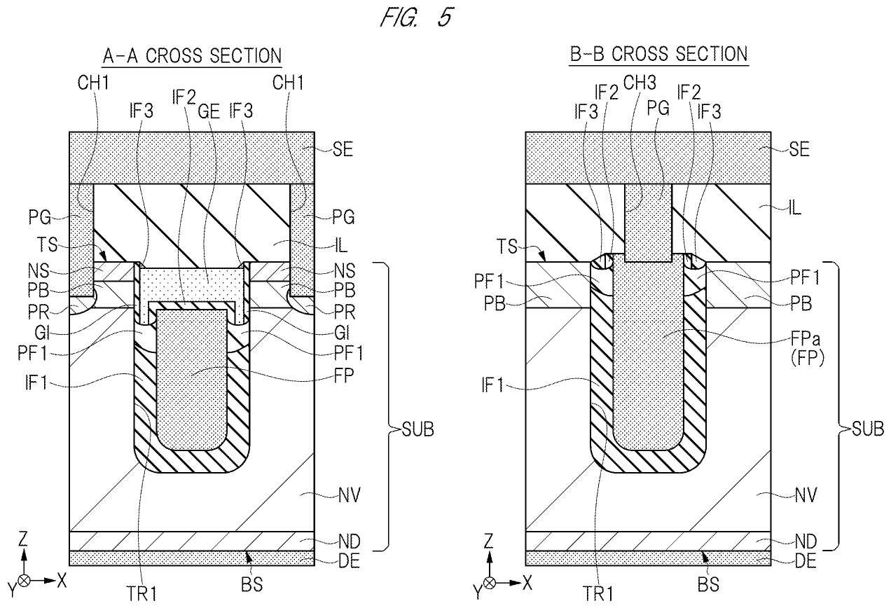

FIG. 1 is a plan view of a semiconductor chip as the semiconductor device 100. FIG. 2 is a plan view of a principal part of an enlarged region 1A of FIG. 1. FIG. 3 illustrates a lower structure of FIG. 2, and mainly illustrates a trench gate structure formed in a semiconductor substrate SUB. Positions of holes CH1 to CH3 of FIG. 2 match with positions of holes CH1 to CH3 of FIG. 3, respectively. FIG. 4 is a plan view illustrating layouts of the field plate electrode FP and the gate electrode GE. FIG. 5 is a cross sectional view taken along line A-A or line B-B of FIGS. 2 and 3.

FIG. 1 mainly illustrates a wiring pattern formed on the semiconductor substrate SUB. The semiconductor device 100 includes a cell region CR and an outer region OR surrounding the cell region CR in plan view. Main semiconductor elements such as a plurality of MOSFETs are formed in the cell region CR. The outer region OR is used for connecting a gate wiring GW to the gate electrode GE and for forming an outer trench TR2 functioning as a termination region.

As illustrated in FIGS. 1 and 2, most of the cell region CR is covered with a source electrode SE. The gate wiring GW surrounds the source electrode SE in plan view. Although not illustrated here, the source electrode SE and the gate wiring GW are covered with a protective film such as a polyimide film. Openings are provided in a part of the protective film, and the source electrode SE and the gate wiring GW exposed at the openings serve as a source pad SP and a gate pad GP, respectively. When external connection members are connected onto the source pad SP and the gate pad GP, the semiconductor device 100 is electrically connected to other semiconductor chip, a lead frame, a wiring substrate, or the like. Note that the external connection member is, for example, a wire made of aluminum, gold or copper, or a clip made of copper plate or the like.

As illustrated in FIG. 3, a plurality of trenches TR1 are formed in the semiconductor substrate SUB in the cell region CR. The plurality of trenches TR1 are formed in a stripe shape, extend in the Y direction and are mutually adjacent in the X direction.

As illustrated in FIG. 5 (see the cross sectional views taken along the line A-A illustrated in FIGS. 2 and 3), the field plate electrode FP is formed at the lower portion of the trench TR inside the trench TR1, and the gate electrode GE is formed at the upper portion of the trench TR1. The field plate electrode FP and the gate electrode GE extend along the trench TR1 in the Y direction.

As illustrated in FIG. 5 (see the cross sectional views taken along the line B-B illustrated in FIGS. 2 and 3), a part of the field plate electrode FP configures a lead portion FPa. The field plate electrode FP configuring the lead portion FPa is formed not only at the lower portion of the trench TR1 but also at the upper portion of the trench TR1 inside the trench TR1.

An outer trench TR2 is formed in the semiconductor substrate SUB in the outer region OR. The outer trench TR2 extends in the Y direction and the X direction so as to surround the cell region CR. A width of the trench TR2 is the same as that of the trench TR1. The field plate electrode FP (lead portion FPa) is formed inside the trench TR2.

A hole CH3 is formed on the lead portion FPa in the cell region CR. The lead portion FPa is electrically connected to the source electrode SE via the hole CH3. A hole CH2 is formed on the gate electrode GE in the outer region OR. The gate electrode GE is electrically connected to the gate wiring GW via the hole CH2. A hole CH3 is formed on a part of the field plate electrode FP in the outer region OR. The field plate electrode FP is electrically connected to the source electrode SE via the hole CH3.

As illustrated in FIG. 5, the gate electrode GE and the lead portion FPa of the field plate electrode FP are exposed from the semiconductor substrate SUB in the trench TR1. The field plate electrode FP is exposed from the semiconductor substrate SUB in the trench TR2. FIG. 4 illustrates an entire layout of the field plate electrode FP and the gate electrode GE which are exposed. In FIG. 4, the exposed field plate electrode FP is illustrated with a solid line, and the exposed gate electrode GE is illustrated with a dashed line.

A cross sectional structure of the semiconductor device 100 will be described below with reference to FIG. 5.

In the first embodiment, note that a cross sectional view taken along a line C-C of FIGS. 2 and 3 is the same as the cross sectional view taken along the line B-B except in that a sign of the trench TR2 is different. Thus, the description of the cross sectional view taken along the line B-B will also serve as the description of the cross sectional view taken along the line C-C below.

As illustrated in FIG. 5, the semiconductor device 100 includes an n-type semiconductor substrate SUB having an upper surface TS and a lower surface BS. The semiconductor substrate SUB is made of n-type silicon. The semiconductor substrate SUB includes a low-concentration n-type drift region NV. In the present embodiment, the n-type semiconductor substrate SUB itself configures the drift region NV. Note that the semiconductor substrate SUB may have a stacked structure made of an n-type silicon substrate and an n-type semiconductor layer being grown on the silicon substrate while being doped with phosphorus (P) by an epitaxial growth method. In this case, the low-concentration n-type semiconductor layer configures the drift region NV while the high-concentration n-type silicon substrate configures a drain region ND.

The n-type drain region ND is formed at the lower portion of the semiconductor substrate SUB as illustrated in FIG. 5. The drain region ND has a higher impurity concentration than that of the drift region NV. The drain electrode DE is formed under the lower surface BS of the semiconductor substrate SUB. The drain electrode DE is made of, for example, a single-layer metal film such as an aluminum film, a titanium film, a nickel film, a gold film, or a silver film, or a stacked film in which these metal films are appropriately stacked. The drain region ND and the drain electrode DE are formed over the cell region CR and the outer region OR. To the semiconductor substrate SUB (the drain region ND and the drift region NV), a drain potential is supplied from the drain electrode DE.

The plurality of trenches TR1 with a predetermined depth extending from the upper surface TS of the semiconductor substrate SUB toward the lower surface BS of the semiconductor substrate SUB are formed in the semiconductor substrate SUB. A depth of each trench TR1 is, for example, equal to or larger than 5 μm and equal to or smaller than 7 μm. Inside the trench TR1, the field plate electrode FP is formed at the lower portion of the trench TR1 via an insulating film IF1 and a protective film PF1. Inside the trench TR1, the gate electrode GE is formed at the upper portion of the trench TR via a gate insulating film GI. Each of the field plate electrode FP and the gate electrode GE is made of, for example, a polycrystalline silicon film doped with an n-type impurity.

The upper surface of the insulating film IF1 is lower than the upper surface of the field plate electrode FP. The protective film PF1 is formed on the insulating film IF1 inside the trench TR1. The gate insulating film GI is formed on the insulating film IF1 inside the trench TR. An insulating film IF2 is formed so as to cover the field plate electrode FP exposed from the protective film PF1. The gate electrode GE is formed also between the field plate electrode FP exposed from the protective film PF1 and the semiconductor substrate SUB via the gate insulating film GI and the insulating film IF2.

The insulating film IF1 and the protective film PF1 are formed between the semiconductor substrate SUB and the field plate electrode FP. The insulating film IF2 is formed between the gate electrode GE and the field plate electrode FP. The gate insulating film GI is formed between the semiconductor substrate SUB and the gate electrode GE. By these films, the semiconductor substrate SUB, the gate electrode GE, and the field plate electrode FP are electrically insulated from one another. An insulating film IF3 is formed on the gate electrode GE. The insulating film IF3 is made of, for example, a silicon oxide film.

Each of the insulating film IF1, the insulating film IF2 and the gate insulating film GI is made of, for example, a silicon oxide film. A thickness of the insulating film IF1 is larger than each thickness of the insulating film IF2 and the gate insulating film GI. Each thickness of the insulating film IF1 and the protective film PF1 inside the trench TR1 is, for example, equal to or larger than 400 nm and equal to or smaller than 600 nm. Each thickness of the insulating film IF2 and the gate insulating film GI inside the trench TR1 is, for example, equal to or larger than 50 nm and equal to or smaller than 70 nm. Note that these thicknesses are thicknesses in the X direction.

As illustrated in FIG. 5, a p-type body region PB is formed on the upper portion of the semiconductor substrate SUB to be shallower than the trench TR1. An n-type source region NS is formed in the body region PB. The source region NS has a higher impurity concentration than that of the drift region NV.

An interlayer insulating film IL is formed on the upper surface TS of the semiconductor substrate SUB so as to cover the trench TR1. The interlayer insulating film IL is made of, for example, a silicon oxide film. A thickness of the interlayer insulating film IL is, for example, equal to or larger than 700 nm and equal to or smaller than 900 nm.

A hole CH1 which penetrates the interlayer insulating film IL and the source region NS and reaches the body region PB is formed in the interlayer insulating film IL. A high-concentration diffusion region PR is formed at the bottom portion of the hole CH1 in the body region PB. The high-concentration diffusion region PR has a higher impurity concentration than that of the body region PB.

The source electrode SE is formed on the interlayer insulating film IL. The source electrode SE is electrically connected to the source region NS, the body region PB, and the high-concentration diffusion region PR via the hole CH1, and supplies a source potential to these impurity regions.

As illustrated in the B-B cross section in FIG. 5 (see the ross-sectional view taken along the line B-B illustrated in FIGS. 2 and 3), a part of the field plate electrode FP configures the lead portion FPa of the field plate electrode FP. Each upper surface of the insulating film IF1 and the protective film PF1, which are in contact with the lead portion FPa, is higher than each upper surface of the insulating film IF1 and the protective film PF1, which are in contact with the field plate electrode FP other than the lead portion FPa.

The insulating film IF2 is formed on a side surface of the lead portion FPa exposed from the protective film PF1. The insulating film IF3 is formed on the protective film PF1. Note that the insulating film IF3 may not be formed. The body region PB is formed in the semiconductor substrate SUB adjacent to the lead portion FPa. However, the source region NS is not formed in the body region PB.

A hole CH3 which penetrates the interlayer insulating film IL and reaches the lead portion FPa is formed in the interlayer insulating film IL. The source electrode SE is electrically connected to the lead portion FPa via the hole CH3, and supplies a source potential to the field plate electrode FP.

Although not illustrated here, a hole CH2 which penetrates the interlayer insulating film IL and reaches the gate electrode GE is formed in the interlayer insulating film IL. The gate wiring GW is electrically connected to the gate electrode GE via the hole CH2, and supplies a gate potential to the gate electrode GE.

A plug PG is embedded inside each of the holes CH1 to CH3. The plug PG is made of, for example, a barrier metal film and a conductive film formed on the barrier metal film. The barrier metal film is made of a stacked film of a titanium film and a titanium nitride film. The conductive film is, for example, a tungsten film.

Each of the source electrode SE and the gate wiring GW is made of, for example, a barrier metal film and a conductive film formed on the barrier metal film. The barrier metal film is, for example, a titanium tungsten film, and the conductive film is, for example, an aluminum alloy film to which copper or silicon is added.

### Main Feature of First Embodiment

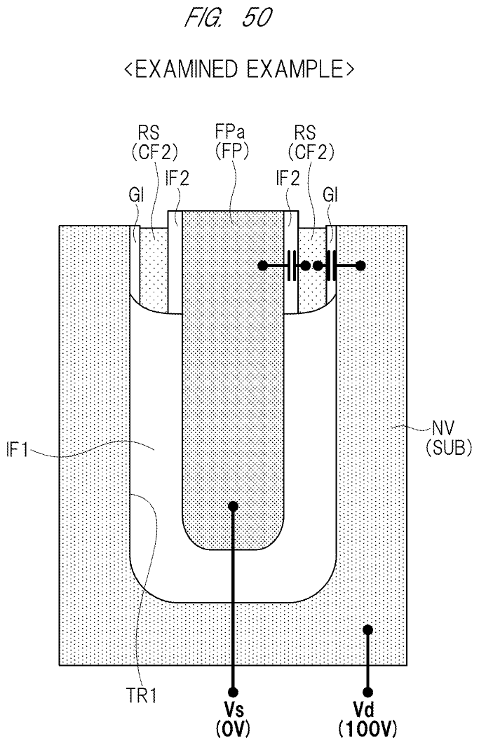

In the first embodiment, the protective film PF1 is formed on the insulating film IF1 as different from an examined example of FIG. 50. More specifically, the protective film PF1 is positioned between the insulating film IF1 and the insulating film IF2 in cross sectional view. Thus, a distance between the upper surface of the lead portion FPa and the upper surface of the protective film PF1 in cross sectional view is shorter than a distance of the examined example. For example, the distance between the upper surface of the lead portion FPa and the upper surface of the protective film PF1 in cross sectional view is equal to or smaller than 100 nm. Therefore, when the conductive film CF2 for the gate electrode GE is etched, the conductive film CF2 formed around the lead portion FPa is removed.

That is, a residue RS as described in the examined example is difficult to be formed on the side surface of the lead portion FPa via the insulating film IF2. Thus, dielectric breakdown between the lead portion FPa and the drift region NV can be maintained, and therefore, reliability of the semiconductor device 100 can be improved.

### <Method of Manufacturing Semiconductor Device>

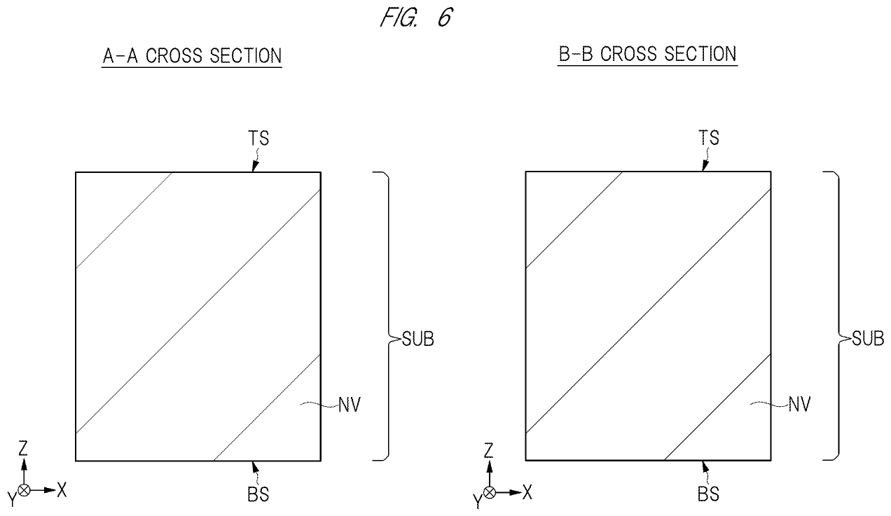

Each manufacturing step included in the method of manufacturing the semiconductor device 100 will be described below with reference to FIGS. 6 to 21.

As illustrated in FIG. 6, first, the n-type semiconductor substrate SUB having the upper surface TS and the lower surface BS is prepared. As described above, the semiconductor substrate SUB may have a stacked structure made of an n-type silicon substrate and an n-type semiconductor layer formed on the silicon substrate by an epitaxial growth method.

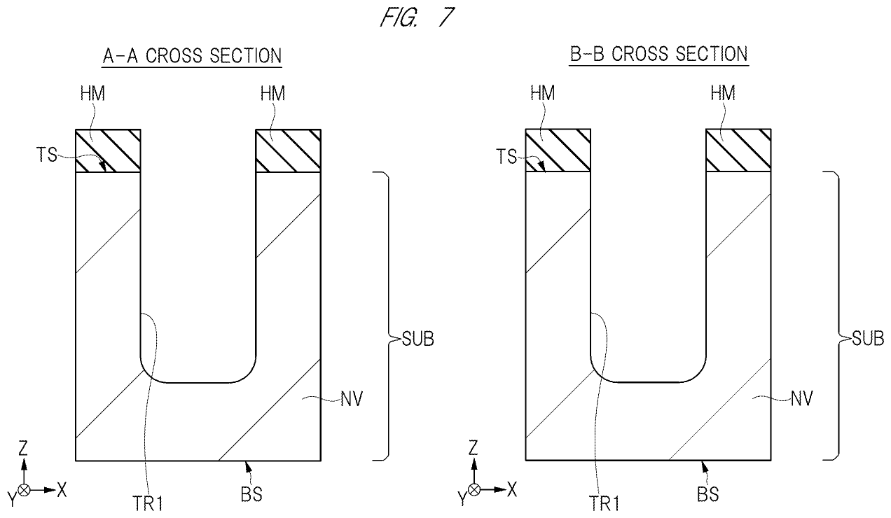

Next, as illustrated in FIG. 7, the trench TR is formed in the semiconductor substrate SUB so as to have a predetermined depth extending from the upper surface TS of the semiconductor substrate SUB toward the lower surface BS of the semiconductor substrate SUB. First, on the semiconductor substrate SUB, for example, a silicon oxide film is formed by, for example, a CVD (Chemical Vapor Deposition) method. Next, the silicon oxide film is patterned by a photolithography technique and an anisotropic etching process to form a hard mask HM. Next, an anisotropic etching process is performed while using the hard mask HM as a mask to form the trench TR in the semiconductor substrate SUB. Then, the hard mask HM is removed by, for example, a wet etching process using a solution containing hydrofluoric acid.

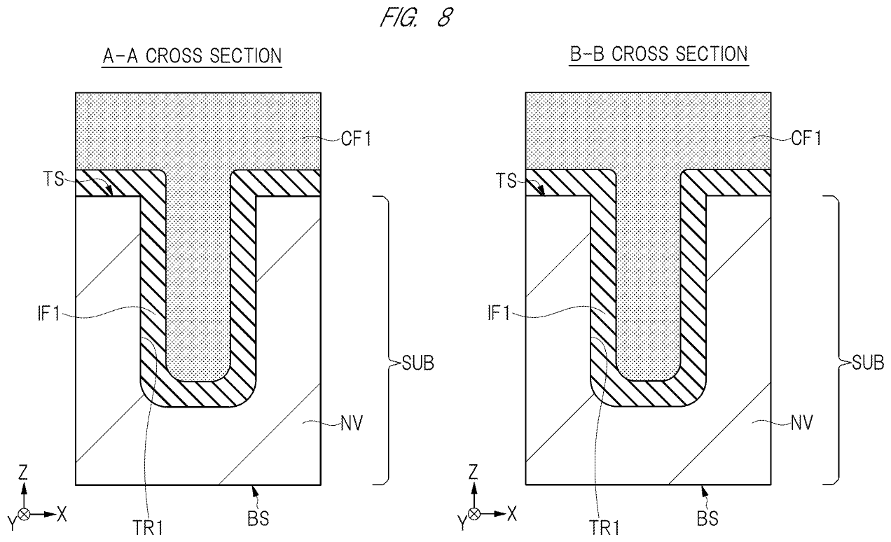

Next, as illustrated in FIG. 8, the insulating film IF1 is formed in the inside of the trench TR1 and on the upper surface TS of the semiconductor substrate SUB. The insulating film IF1 is, for example, a silicon oxide film formed by a thermal oxidization process. Note that the insulating film IF1 may be a stacked film made of a first silicon oxide film formed by a thermal oxidization process and a second silicon oxide film formed on the first silicon oxide film by a CVD method.

Next, the conductive film CF1 is formed on the insulating film IF1 by, for example, a CVD method so as to fill the inside of the trench TR1. The conductive film CF1 is, for example, an n-type polycrystalline silicon film. In order to favorably fill the conductive film CF1 into the trench TR1, the conductive film CF1 may be formed by a plurality of separate processes (such as two separate processes for formation of a first polycrystalline silicon film and formation of a second polycrystalline silicon film).

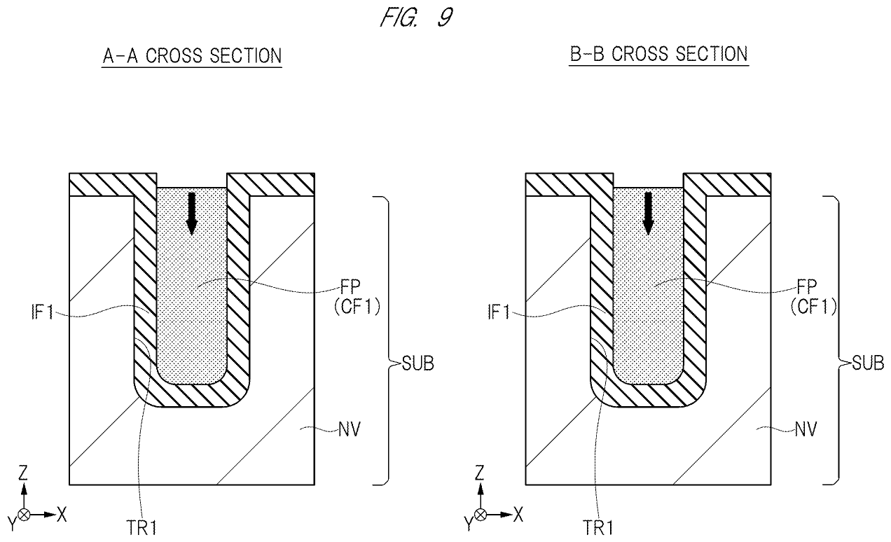

Next, as illustrated in FIG. 9, the conductive film CF1 located outside the trench TR1 is removed to form the conductive film CF1 left inside the trench TR as the field plate electrode FP.

Specifically, first, the conductive film CF1 formed outside the trench TR1 is removed by, for example, a polishing process using a chemical mechanical polishing (CMP) method. Next, for example, by an etching process using SF₆ gas, the upper surface of the conductive film CF1 located inside the trench TR is recessed toward the bottom portion of the trench TR1 (that is, in a direction of an arrow illustrated in FIG. 9). In this manner, the conductive film CF1 left inside the trench TR is formed as the field plate electrode FP.

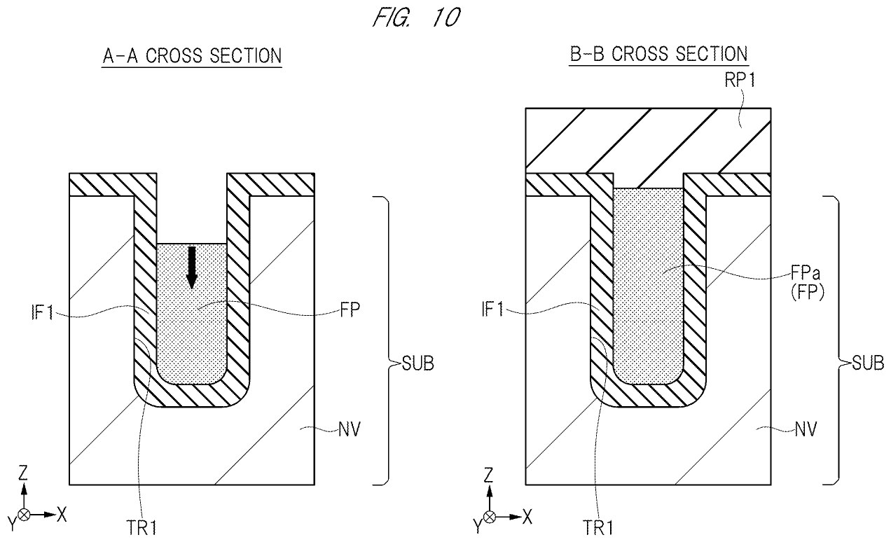

Next, as illustrated in FIG. 10, in order to leave a part of the field plate electrode FP as the lead portion FPa, another part of the field plate electrode FP is selectively removed.

Specifically, first, as illustrated in the B-B cross section, a resist pattern RP1 selectively covering a part of the field plate electrode FP which is to be the lead portion FPa is formed. Next, by, for example, an etching process using SF₆ gas while using the resist pattern RP1 as a mask, a part of the field plate electrode FP which is not to be the lead portion FPa is removed. That is, as illustrated in the A-A cross section in FIG. 10 (the cross sectional view taken along the line A-A illustrated in FIGS. 2 and 3), another part of the field plate electrode FP which is not to be the lead portion FPa is selectively recessed toward the bottom portion of the trench TR1 (namely, in a direction of an arrow illustrated in FIG. 10). A not-recessed part of the field plate electrode FP becomes the lead portion FPa. Then, the resist pattern RP1 is removed by an ashing process.

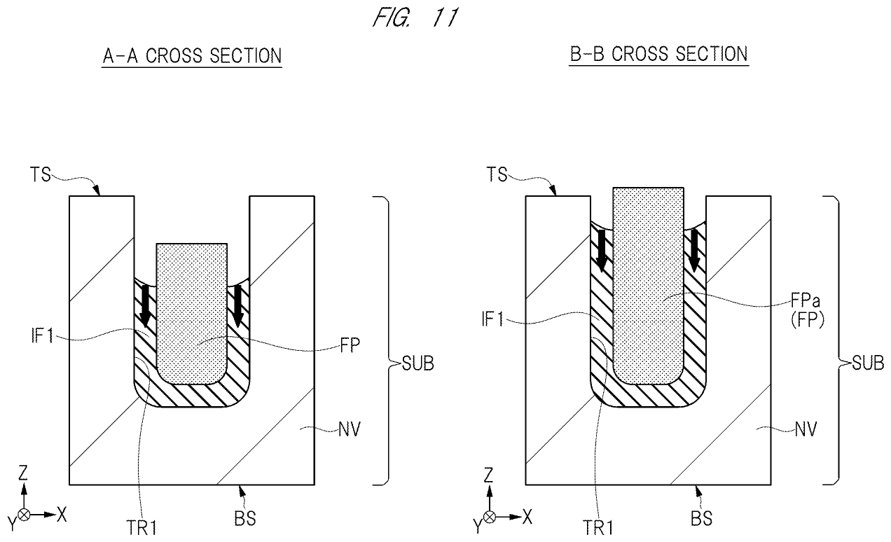

Next, as illustrated in FIG. 11, an isotropic etching process using solution containing hydrofluoric acid is performed to the insulating film IF1. In this manner, the insulating film IF1 on the upper surface TS of the semiconductor substrate SUB is removed, and the insulating film IF1 inside the trench TR1 is recessed toward the bottom portion of the trench TR1 (in other words, in a direction of an arrow of FIG. 11) such that the upper surface of the insulating film IF1 inside the trench TR1 is positioned lower than the upper surface of the field plate electrode FP in cross sectional view.

At this time, the upper surface of the insulating film IF1 contacting with the field plate electrode FP other than the lead portion FPa is positioned lower than the upper surface of the insulating film IF1 contacting with the field plate electrode FP of the lead portion FPa. The insulating film IF1 on the upper surface TS of the semiconductor substrate SUB is removed, and therefore, the upper surface of the lead portion FPa is positioned higher than the upper surface TS of the semiconductor substrate SUB as illustrated in the B-B cross section in FIG. 11.

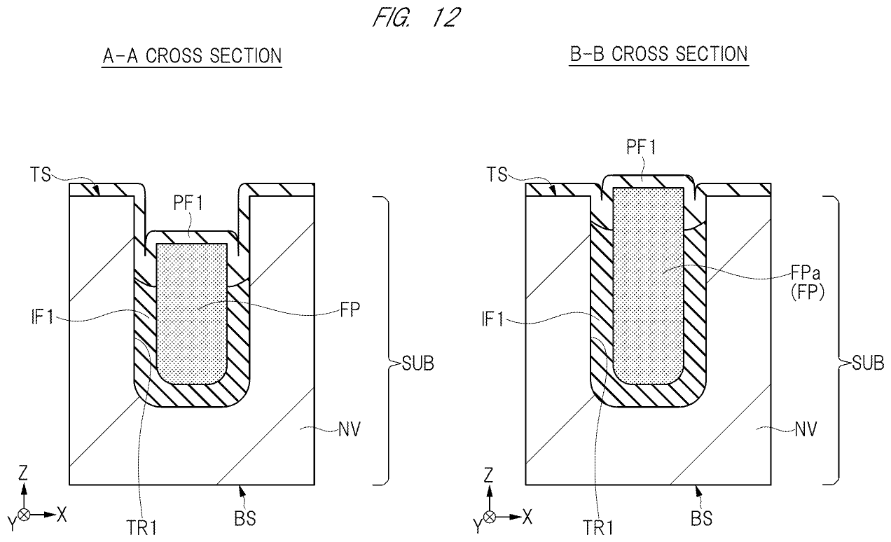

Next, as illustrated in FIG. 12, the protective film PF1 is formed on the upper surface TS of the semiconductor substrate SUB and in the inside of the trench TR1 by, for example, a CVD method so as to cover the field plate electrode FP and the insulating film IF1. The protective film PF1 is an insulating film such as a silicon oxide film.

The protective film PF1 formed on the upper surface TS of the semiconductor substrate SUB is thinner than the insulating film IF1 formed on the upper surface TS of the semiconductor substrate SUB in the step of FIG. 8. The thickness of the insulating film IF1 on the upper surface TS of FIG. 8 is, for example, equal to or larger than 400 nm and equal to or smaller than 600 nm. The thickness of the protective film PF1 on the upper surface TS of FIG. 12 is, for example, equal to or larger than 200 nm and equal to or smaller than 300 nm.

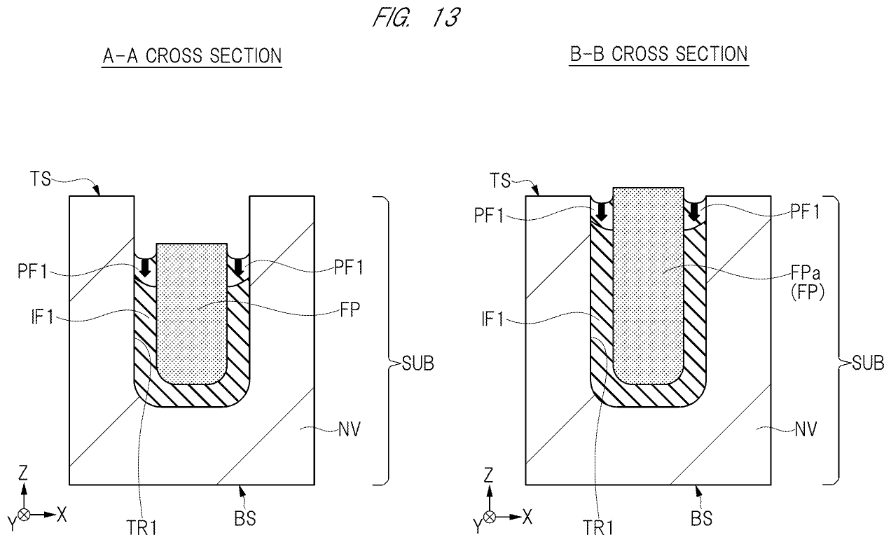

Next, as illustrated in FIG. 13, an isotropic etching process using solution containing hydrofluoric acid is performed to the protective film PF1. In this manner, the protective film PF1 on the upper surface TS of the semiconductor substrate SUB is removed, and the protective film PF1 inside the trench TR1 is recessed toward the bottom portion of the trench TR1 (in other words, in a direction of an arrow of FIG. 13) such that the upper surface of the protective film PF1 inside the trench TR1 is positioned lower than the upper surface of the field plate electrode FP in cross sectional view.

Since the protective film PF1 formed in the step of FIG. 12 is thinner than the insulating film IF1 formed in the step of FIG. 8 as described above, time for the isotropic etching process of FIG. 13 is shorter than time for the isotropic etching process of FIG. 11. Thus, an amount of the film to be removed by the etching process of FIG. 13 is more easily adjusted (controlled) than an amount of the film to be removed by the etching process of FIG. 11. Thus, inside the trench TR1, a recessed amount of the protective film PF1 is smaller than a recessed amount of the insulating film IF1. Therefore, as illustrated in the B-B cross section, the upper surface of the protective film PF1 can be made closer to the upper surface TS of the semiconductor substrate SUB and the upper surface of the lead portion FPa. At this time, the distance between the upper surface of the lead portion FPa and the upper surface of the protective film PF1 in cross sectional view is equal to or smaller than 100 nm.

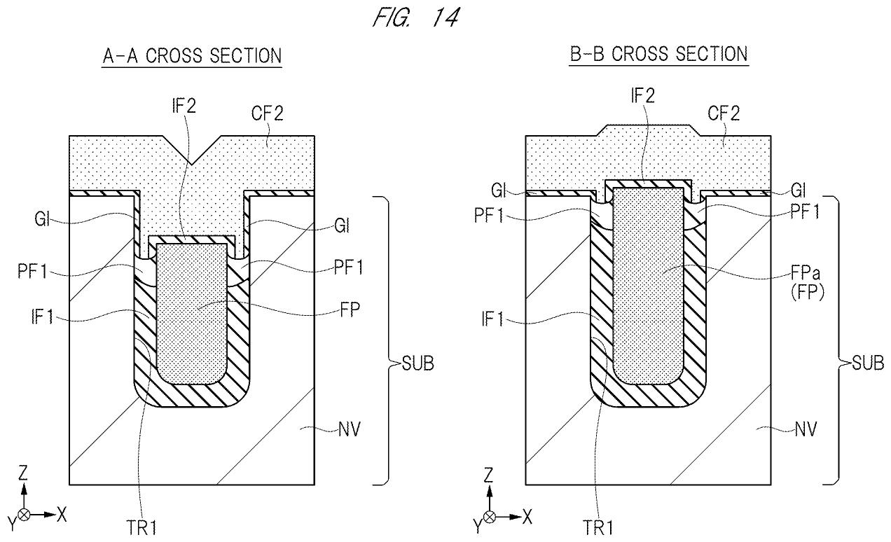

Next, a thermal oxidization process is performed to form the gate insulating film GI on the protective film PF1 inside the trench TR1 and forming the insulating film IF2 so as to cover the field plate electrode FP exposed from the protective film PF1 as illustrated in FIG. 14.

Next, the conductive film CF2 is formed on the gate insulating film GI, the insulating film IF2, and the protective film PF1 by, for example, a CVD method so as to fill the inside of the trench TR1. The conductive film CF2 is, for example, an n-type polycrystalline silicon film.

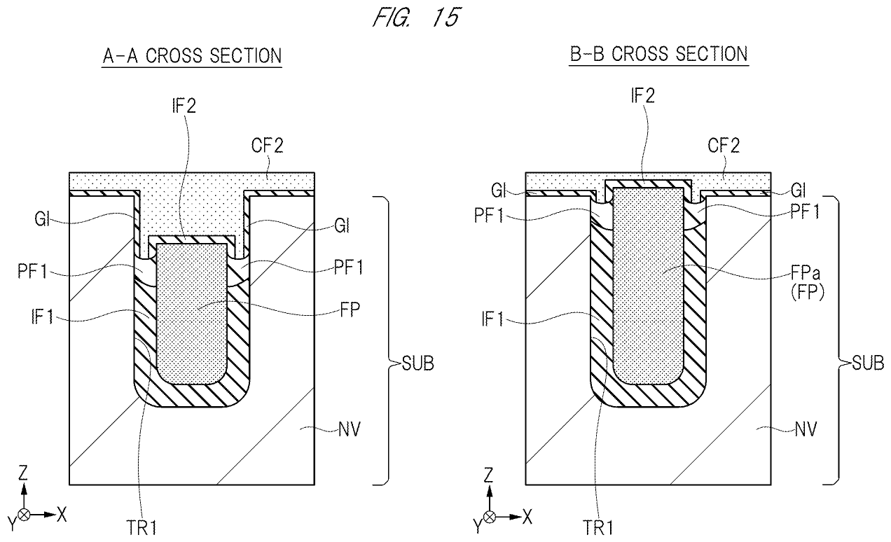

Next, as illustrated in FIG. 15, a polishing process using a CMP method is performed to the conductive film CF2. In this manner, the conductive film CF2 is thinned to planarize the upper surface of the conductive film CF2.

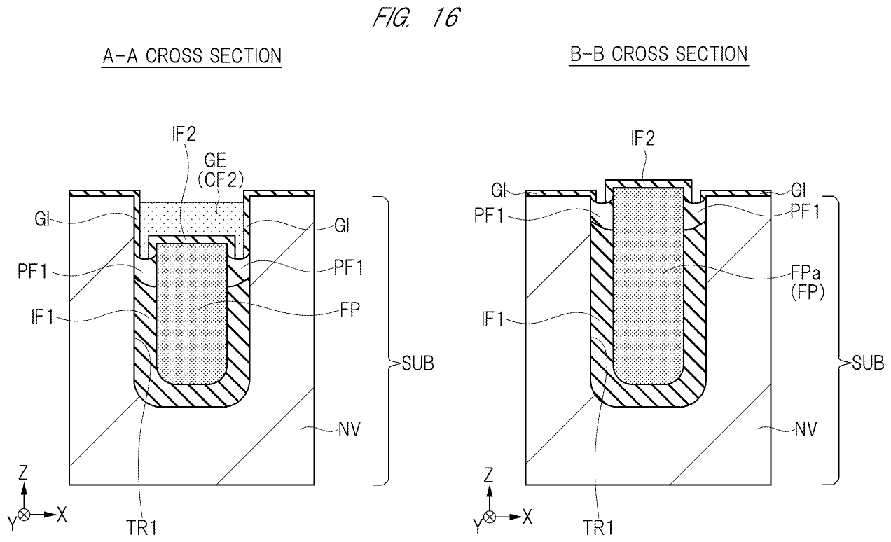

Next, as illustrated in FIG. 16, an anisotropic etching process is performed to the conductive film CF2 to remove the conductive film CF2 outside the trench TR1. In this manner, the conductive film CF2 left on the field plate electrode FP inside the trench TR1 is formed as the gate electrode GE.

Note that the anisotropic etching process is performed in an over-etching manner in order to completely remove the conductive film CF2 outside the trench TR1. Thus, as illustrated in the A-A cross section in FIG. 16, the upper surface of the gate electrode GE is positioned slightly lower than the upper surface TS of the semiconductor substrate SUB.

The conductive film CF2 formed on the protective film PF1 and the insulating film IF2, which are in contact with the lead portion FPa, is removed by this anisotropic etching process. That is, in the present embodiment, since the protective film PF1 is previously formed on the insulating film IF1 as described above, the residue RS as described in the examined example is difficult to be formed on the side surface of the lead portion FPa via the insulating film IF2 at the end of the step of FIG. 16. Thus, the dielectric breakdown between the lead portion FPa and the drift region NV can be maintained, and therefore, reliability of the semiconductor device 100 is improved.

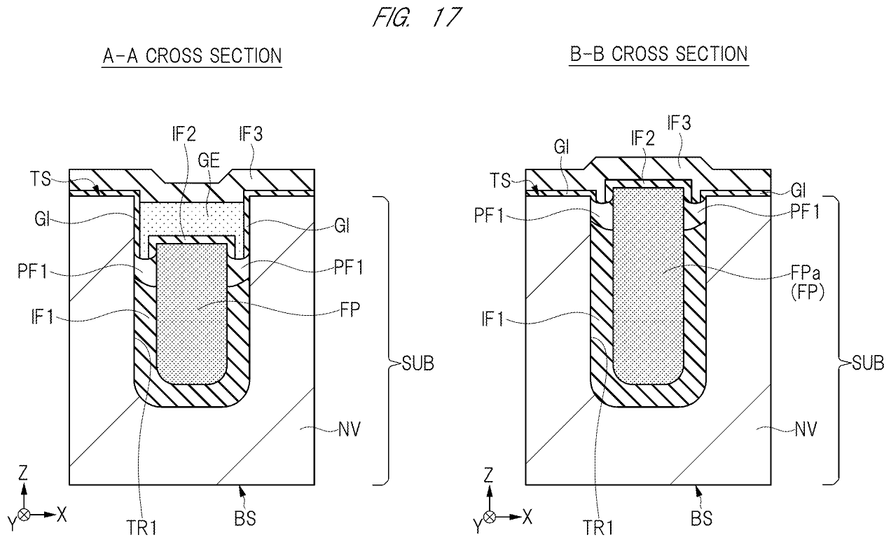

Next, as illustrated in FIG. 17, the insulating film IF3 is formed on the upper surface TS of the semiconductor substrate SUB and on the gate electrode GE so as to cover the trench TR1 by, for example, a CVD method.

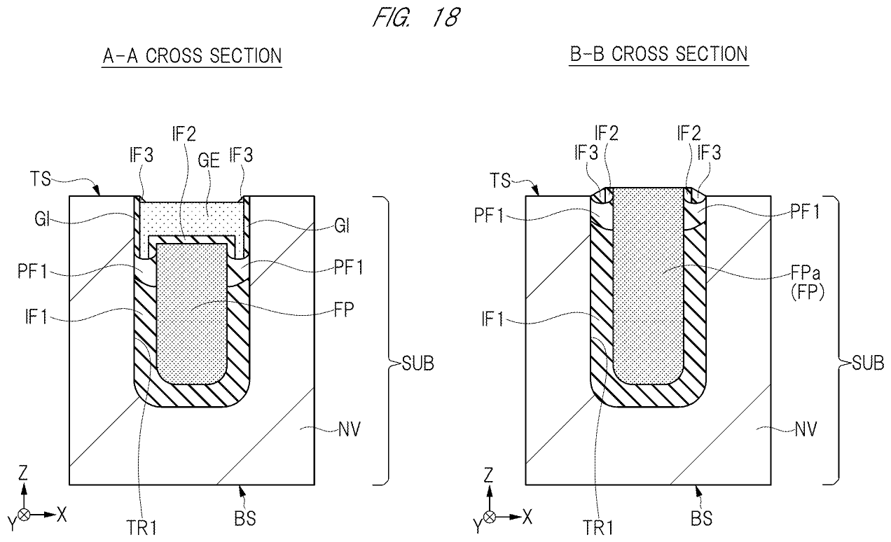

Next, as illustrated in FIG. 18, an anisotropic etching process is performed to the insulating film IF3. In this manner, as illustrated in the A-A cross section, the insulating film IF3 is left on the upper surface of part of the gate electrode GE to be in contact with the gate insulating film GI inside the trench TR1. And, as illustrated in the B-B cross section, the insulating film IF3 is left on the side surface of the lead portion FPa via the insulating film IF2. By this anisotropic etching process, the gate insulating film GI on the upper surface TS of the semiconductor substrate SUB and the insulating film IF2 on the upper surface of the lead portion FPa are also removed. Since the gate insulating film GI inside the trench TR1 is covered with the remaining insulating film IF3 as described above, the gate insulating film GI on the upper surface TS of the semiconductor substrate SUB is removed while the gate insulating film GI inside the trench TR1 is left as illustrated in the A-A cross section by the anisotropic etching process.

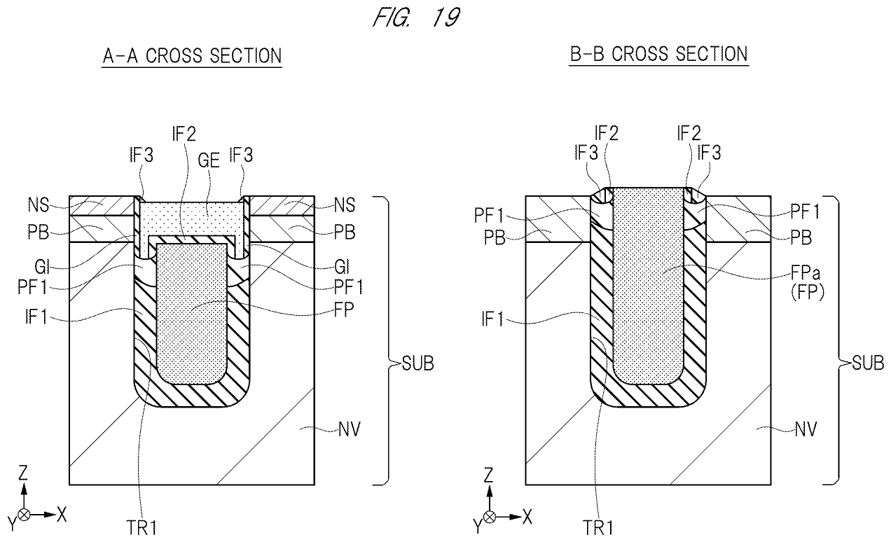

Next, as illustrated in FIG. 19, the semiconductor substrate SUB is doped with, for example, boron (B) by a photolithography technique and an ion implantation method, so that the p-type body region PB is selectively formed in the semiconductor substrate SUB. The body region PB is made shallower than the trench TR1.

Next, the semiconductor substrate is doped with, for example, arsenic (As) by a photolithography technique and an ion implantation method, so that the n-type source region NS is selectively formed in the body region PB in the cell region CR. Note that the n-type source region NS is not formed in the body region PB adjacent to the lead portion FPa. Then, a heat process is performed to the semiconductor substrate SUB to diffuse the impurities contained in the source region NS and the body region PB.

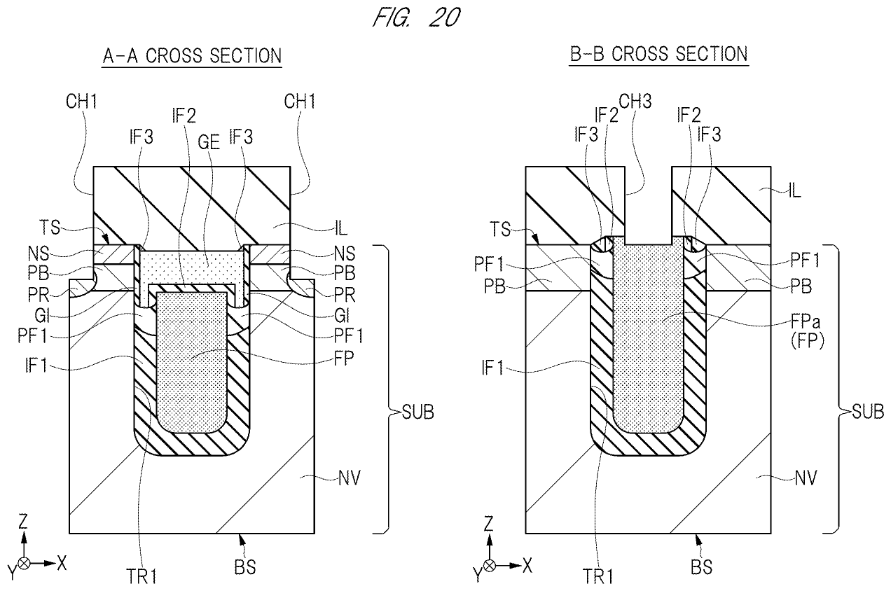

Next, as illustrated in FIG. 20, the interlayer insulating film IL is formed on the upper surface TS of the semiconductor substrate SUB so as to cover the trench TR1 by, for example, a CVD method.

Then, the holes CH1 to CH3 are formed in the interlayer insulating film IL. First, a resist pattern which has a pattern opening (exposing) the semiconductor substrate SUB where the source region NS is formed is formed on the interlayer insulating film IL. Next, by an anisotropic etching process using the resist pattern as a mask, the hole CH1 which penetrates through each of the interlayer insulating film IL and the source region NS and reaches inside of the body region PB is formed. Next, the body region PB at the bottom portion of the hole CH1 is doped with, for example, boron (B) by an ion implantation method, so that the p-type high-concentration diffusion region PR is formed. Then, the resist pattern is removed by an ashing process.

Next, a resist pattern which has a pattern opening (exposing) the lead portion FPa and the gate electrode GE is formed on the interlayer insulating film IL. Next, by an anisotropic etching process using the resist pattern as a mask, the hole CH3 which penetrates through the interlayer insulating film IL and reaches the lead portion FPa is formed. Although not illustrated here, in the step of forming the hole CH3, the hole CH2 which penetrates through the interlayer insulating film IL and reaches the gate electrode GE is also formed. Then, the resist pattern is removed by an ashing process.

Regarding an order of the formations of the holes CH1 to CH3, note that any hole may be formed first.

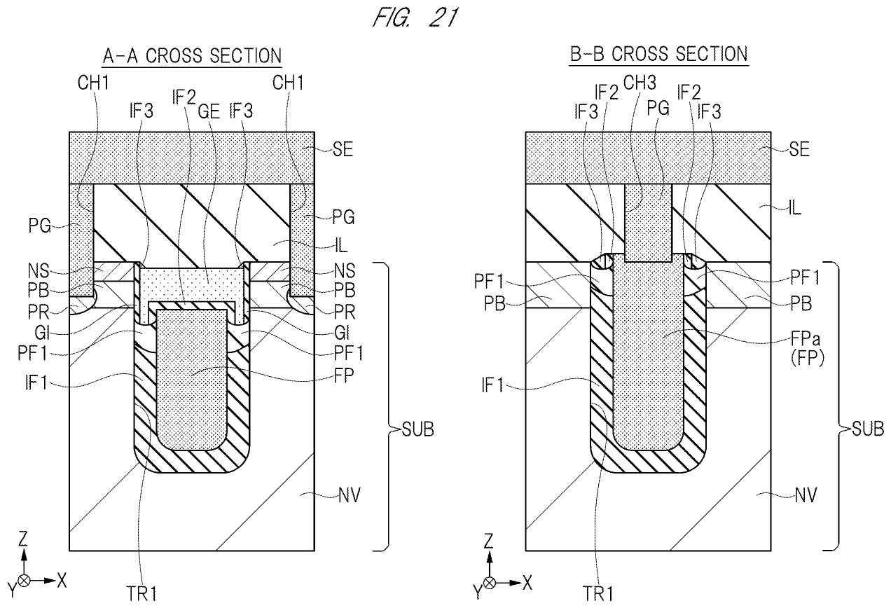

Next, as illustrated in FIG. 21, the plugs PG are formed inside the holes CH1 to CH3, respectively, and the source electrode SE and the gate wiring GW are formed on the interlayer insulating film IL.

Specifically, first, a first barrier metal film is formed inside the holes CH1 to CH3 and on the interlayer insulating film IL by a sputtering method or a CVD method. The first battier metal film is, for example, a stacked film made of a titanium nitride film and a titanium film. Next, a first conductive film is formed on the first barrier metal film by a CVD method. The first conductive film is made of, for example, a tungsten film. Next, the first barrier metal film and the first conductive film formed outside the holes CH1 to CH3 are removed by a CMP method or an anisotropic etching process. In this manner, the plugs PG made of the first barrier metal film and the first conductive film are formed so as to fill insides of the holes CH1 to CH3.

Next, a second barrier metal film is formed on the interlayer insulating film IL by a sputtering method. The second barrier metal film is made of, for example, a titanium tungsten film. Next, a second conductive film is formed on the second barrier metal film by a sputtering method. The second conductive film is, for example, an aluminum alloy film to which copper or silicon is added. Next, the second barrier metal film and the second conductive film are patterned to form the source electrode SE and the gate wiring GW.

Next, although not illustrated here, a protective film made of, for example, a polyimide film is formed on the source electrode SE and the gate wiring GW by, for example, a coating method. A part of the protective film is opened to expose regions which are to be the source pad SP and the gate pad GP in the source electrode SE and the gate wiring GW.

Then, the structure illustrated in FIG. 5 is provided through the following manufacturing steps. First, the lower surface BS of the semiconductor substrate SUB is polished as needed. Next, the lower surface BS of the semiconductor substrate SUB is doped with, for example, arsenic (As) or the like by an ion implantation method, so that the n-type drain region ND is formed. When the semiconductor substrate SUB is made of a stacked structure of an n-type silicon substrate and an n-type semiconductor layer, the drain region ND is made of the high-concentration n-type silicon substrate, and therefore, the formation of the drain region ND by the ion implantation method can be omitted. Next, the drain electrode DE is formed on the lower surface BS of the semiconductor substrate SUB by a sputtering method.

### Second Embodiment

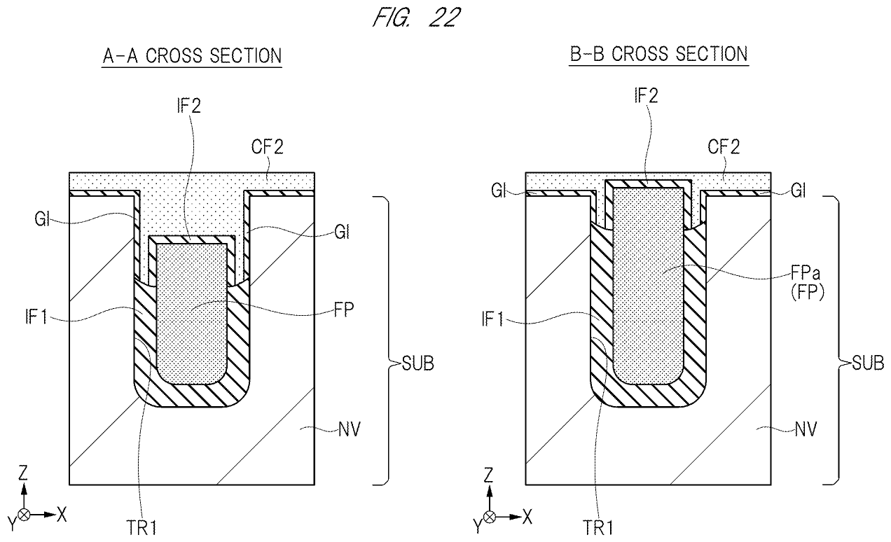

A semiconductor device 100 according to a second embodiment will be described below with reference to FIGS. 22 to 26. In the following explanation, note that differences from the first embodiment will be mainly described, and description of overlapping points with the first embodiment will be omitted.

While the protective film PF1 suppresses the formation of the residue RS of the conductive film CF2 in the first embodiment, the residue RS is removed by an anisotropic etching process using a resist pattern RP2 in the second embodiment. Note that FIG. 22 illustrates a manufacturing step continued from FIG. 11 of the first embodiment.

First, a thermal oxidization process is performed to form the gate insulating film GI on the insulating film IF1 inside the trench TR1 and to form the insulating film IF2 so as to cover the field plate electrode FP exposed from the insulating film IF1 as illustrated in FIG. 22.

Next, the conductive film CF2 is formed on the gate insulating film GI, on the insulating film IF2 and on the insulating film IF1 so as to fill inside the trench TR1 by, for example, a CVD method. Next, a polishing process using a CMP method is performed to the conductive film CF2.

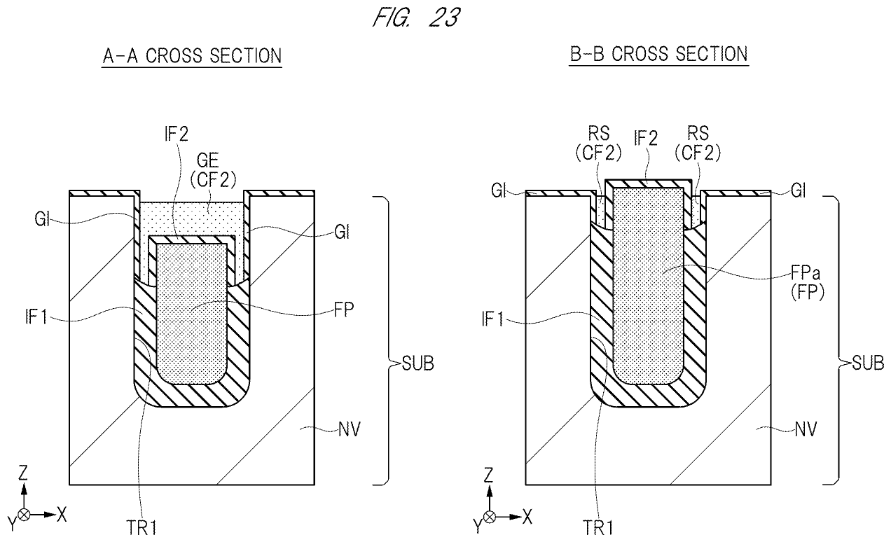

Next, as illustrated in FIG. 23, when an anisotropic dry etching process is performed to the conductive film CF2, the conductive film CF2 formed outside the trench TR1 is removed. In this manner, the conductive film CF2 left on the field plate electrode FP inside the trench TR1 is formed as the gate electrode GE.

By this anisotropic dry etching process, the conductive film CF2 formed on the upper surface of the lead portion FPa via the insulating film IF2 is removed while the residue RS of the conductive film CF2 may be left on the side surface of the lead portion FPa via the insulating film IF2.

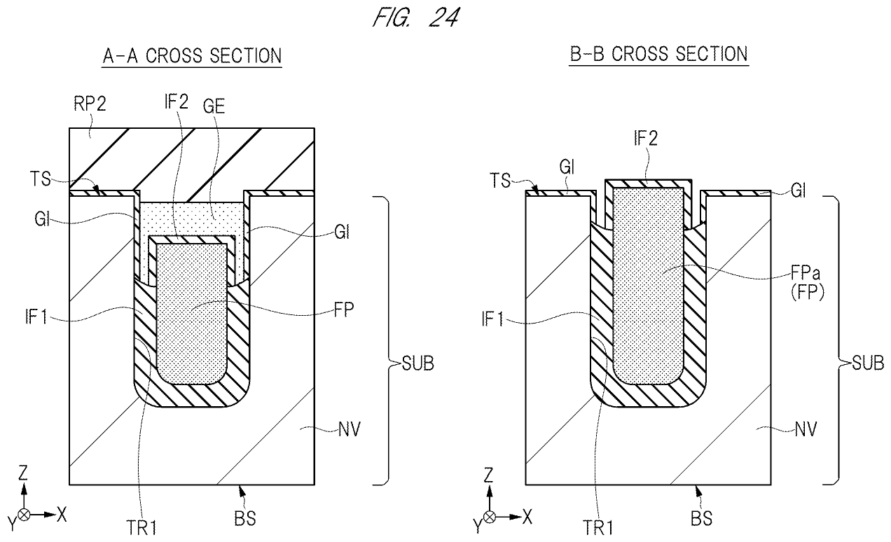

Next, as illustrated in FIG. 24, first, the resist pattern RP2 which has a pattern selectively opening (exposing) the lead portion FPa in the field plate electrode FP is formed on the upper surface TS of the semiconductor substrate SUB. The field plate electrode FP other than the lead portion FPa is covered with the resist pattern RP2.

Next, an anisotropic etching process is performed to the conductive film CF2 while using the resist pattern RP2 as a mask. The anisotropic etching process is performed under a condition making the gate insulating film GI and the insulating film IF2 difficult to be etched while making the conductive film CF2 easy to be etched. In this manner, even if the residue RS is left on the side surface of the lead portion FPa via the insulating film IF2, the residue RS can be completely removed.

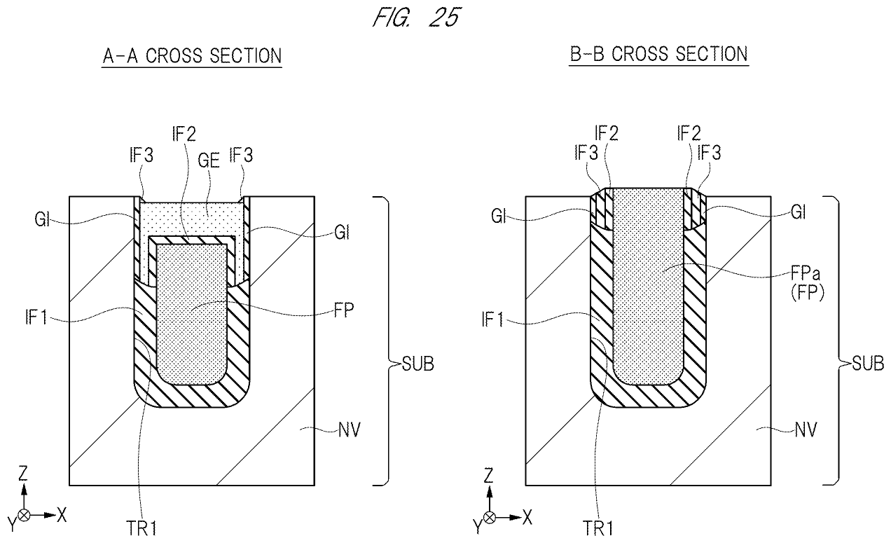

Next, as illustrated in FIG. 25, the insulating film IF3 is formed on the upper surface of the semiconductor substrate SUB so as to cover the trench TR1 by, for example, a CVD method. Next, an anisotropic etching process is performed to the insulating film IF3. In this manner, as illustrated in the A-A cross section, the insulating film IF3 is left on the upper surface of part of the gate electrode GE to be in contact with the gate insulating film GI. And, as illustrated in the B-B cross section, the insulating film IF3 is left on the side surface of the lead portion FPa via the insulating film IF2. That is, the region (gap) from which the residue RS is removed in the earlier step is closed by the insulating film IF3.

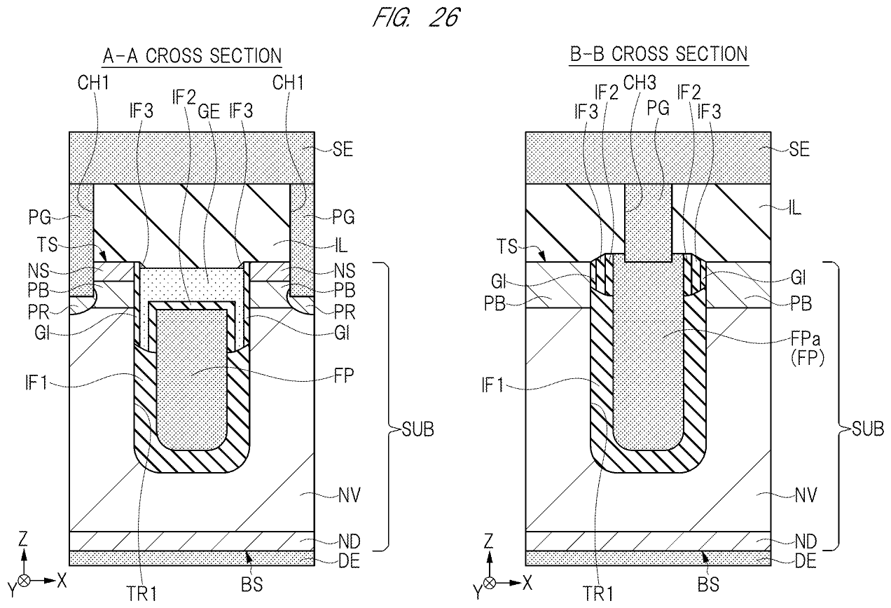

Then, by the manufacturing steps similar to those of FIG. 19 and continued steps of the first embodiment, a structure of FIG. 26 is formed. As described above, even in the second embodiment, the residue RS of the conductive film CF2 on the side surface of the field plate electrode FP (lead portion FPa) is removed, and therefore, reliability of the semiconductor device 100 can be improved.

Note that the technique of the second embodiment can be also applied to each embodiment such as the first embodiment. For example, after the anisotropic etching process onto the conductive film CF2 in the first embodiment (see FIG. 16) but before the formation of the insulating film IF3 (see FIG. 17), the anisotropic etching process using the resist pattern RP2 of FIG. 24 in the second embodiment may be performed. Thus, even if the conductive film CF2 cannot be completely removed by the anisotropic etching process onto the conductive film CF2 to leave the residue RS of the conductive film CF2 on the side surface of the lead portion FPa via the insulating film IF2, this residue RS can be exactly removed by the anisotropic etching process of FIG. 24 in the second embodiment.

### First Examined Example

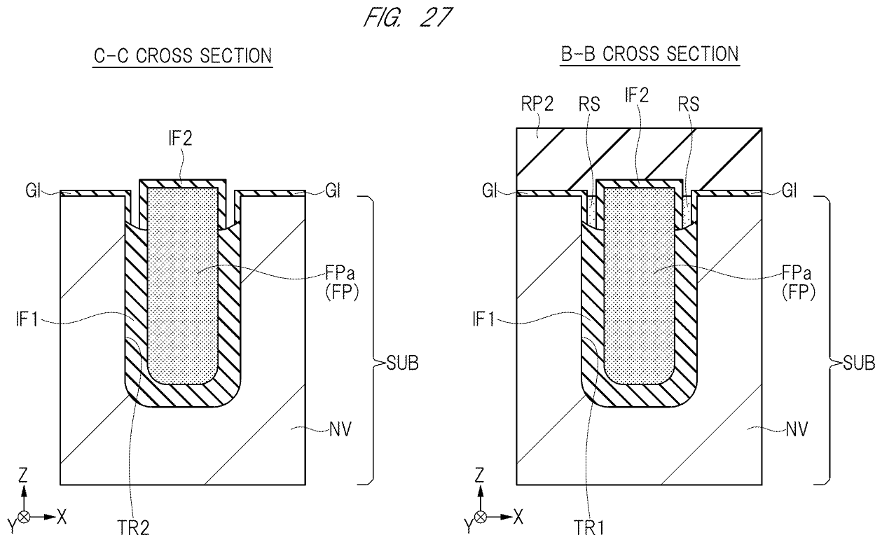

A semiconductor device 100 according to a first examined example of the second embodiment will be described below with reference to FIGS. 27 to 29.

The technique of the second embodiment is basically performed to all the lead portions FPa formed in the semiconductor device 100. However, in the first examined example, the technique of the second embodiment is performed to some lead portions FPa.

Specifically, the technique of the second embodiment is performed to the “field plate electrode FP (lead portions FPa) in the outer trench TR2” illustrated in FIG. 4. That is, the residue RS is removed from the outer trench TR2 as illustrated in the cross section taken along the line C-C of FIG. 3.

On the other hand, the technique of the second embodiment is not performed to the “field plate electrode FP in the cell region CR,” the “field plate electrode FP at the end portion of the cell region CR,” and the “field plate electrode FP under the gate pad GP” illustrated in FIG. 4. The technique of the second embodiment is not performed to at least for the “field plate electrode FP in the cell region CR” to intentionally leave the residue RS.

In FIG. 24 of the second embodiment, the resist pattern RP2 covers the field plate electrode FP other than the lead portion FPa. In the first examined example, as illustrated in FIG. 27, the resist pattern RP2 covers not only the field plate electrode FP other than the lead portion FPa but also the lead portion FPa in the cell region CR to open the lead portion FPa in the outer region OR. In this state, an anisotropic etching process similar to that of the second embodiment is performed to the conductive film CF2 while using the resist pattern RP2 as a mask.

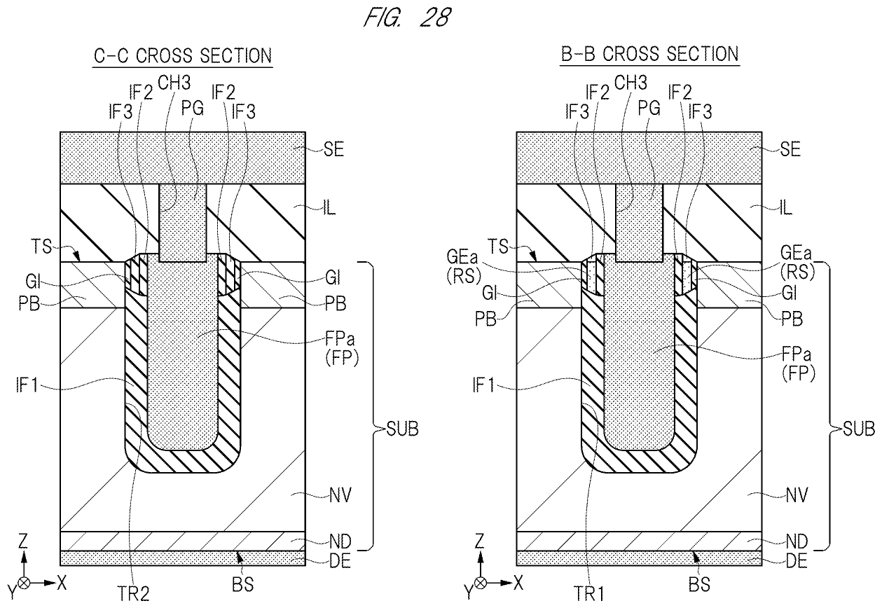

The residue RS formed on the side surface of the field plate electrode FP (lead portion FPa) in the outer trench TR2 is removed by the anisotropic etching process. On the other hand, the residue RS formed on the side surface of the lead portion FPa in the trench TR1 is left as part of the gate electrode GE. As illustrated in FIG. 28, the left part of the gate electrode GE is to be a joint portion GEa. The joint portion GEa is formed on both side surfaces of the lead portion FPa via the insulating film IF2 in the X direction.

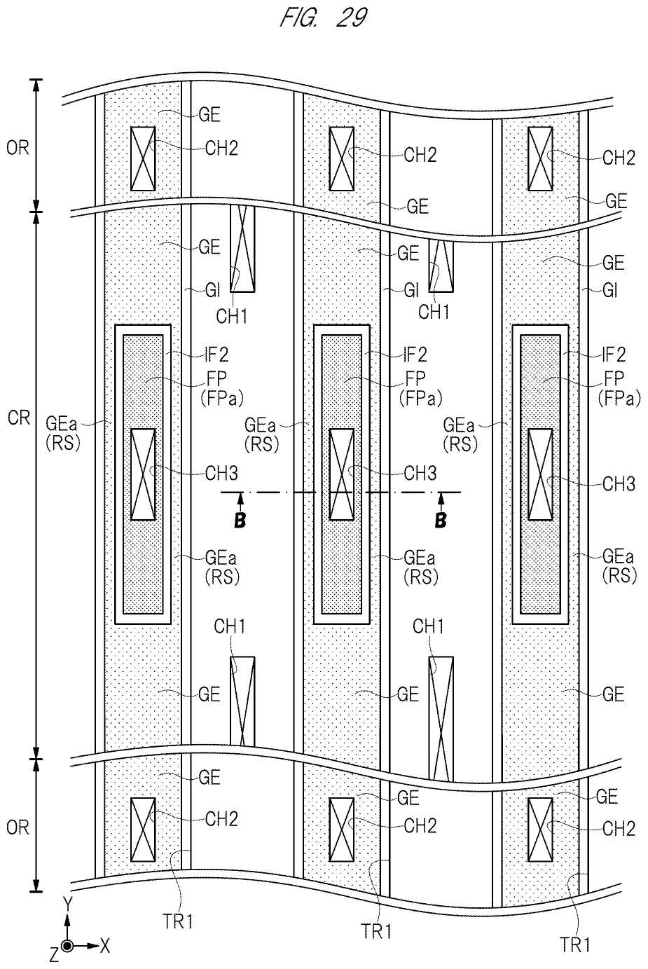

FIG. 29 is a plan view mainly illustrating a partially enlarged part of the gate electrode GE in the trench gate of FIG. 4.

The gate electrode GE includes a first end portion in the Y direction and a second end portion opposite to the first end portion in the Y direction. Note that the first end portion is an end portion of the gate electrode GE positioned at the outer region OR on the upper side of the drawing, and the second end portion is an end portion of the gate electrode GE positioned at the outer region OR on the lower side of the drawing.

The lead portion FPa is formed inside the trench TR1 between the gate electrode GE at the first end portion side and the gate electrode GE at the second end portion side. That is, the gate electrode GE is vertically divided by the lead portion FPa in the drawing.

For example, in forming the hole CH2, the hole CH2 may not reach the gate electrode GE due to an insufficient etched amount. That is, there is a risk of failure to open the hole CH2 at either the first end portion side or the second end portion side. Thus, there is a problem of failure to function the MOSFET using the gate electrode GE at either the first end portion side or the second end portion side.

For solving such a problem, in the first examined example, the joint portion GEa is provided on the side surface of the lead portion FPa. Inside the trench TR1 where the lead portion FPa is formed, the joint portion GEa connects the gate electrode GE at the first end portion side and the gate electrode GE at the second end portion side.

For example, even if a gate potential is not directly supplied to the gate electrode GE at the second end portion side since the hole CH2 at the second end portion side is not opened, the gate potential is supplied from the gate electrode GE at the first end portion side via the joint portion GEa to the gate electrode GE at the second end portion side. Thus, the above-described problem can be solved.

As described above, according to the first examined example, the residue RS in the outer region OR can be removed, and the MOSFET using the gate electrode GE in the cell region CR can be normally functioned. Thus, reliability of the semiconductor device 100 can be further improved.

### Third Embodiment

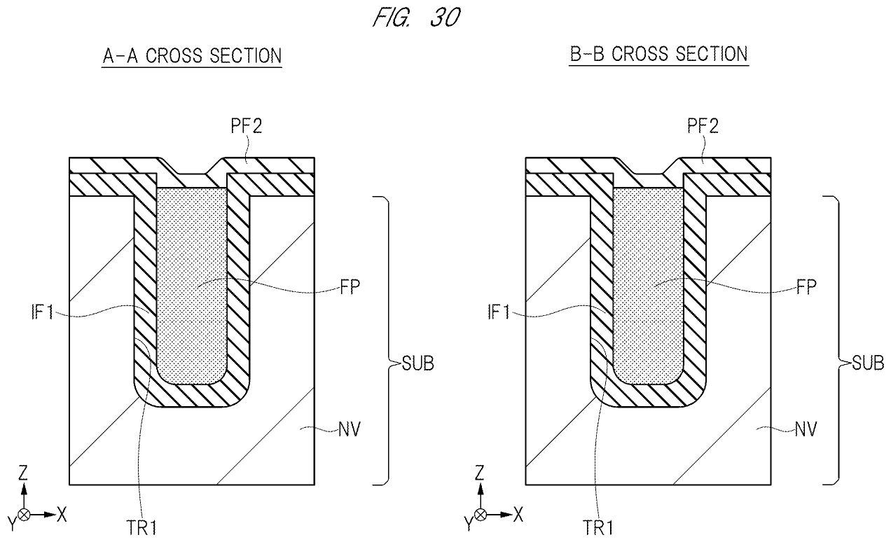

A semiconductor device 100 according to a third embodiment will be described below with reference to FIGS. 30 to 34. In the following explanation, differences from the first embodiment will be mainly described, and the overlapping points with the first embodiment will not be described.

In the third embodiment, a protective film PF2 is further formed on the insulating film IF1 formed on the upper surface TS of the semiconductor substrate SUB to suppress the formation of the residue RS. Note that FIG. 30 illustrates a manufacturing step continued from FIG. 9 of the first embodiment.

As illustrated in FIG. 30, the protective film PF2 is formed so as to cover the field plate electrode FP and the insulating film IF1 on the upper surface TS of the semiconductor substrate SUB by, for example, a CVD method. The protective film PF2 is, for example, a silicon oxide film. A thickness of the protective film PF2 is, for example, equal to or larger than 200 nm and equal to or smaller than 550 nm, and is smaller than a thickness of the silicon oxide film etched by an isotropic etching process describe later.

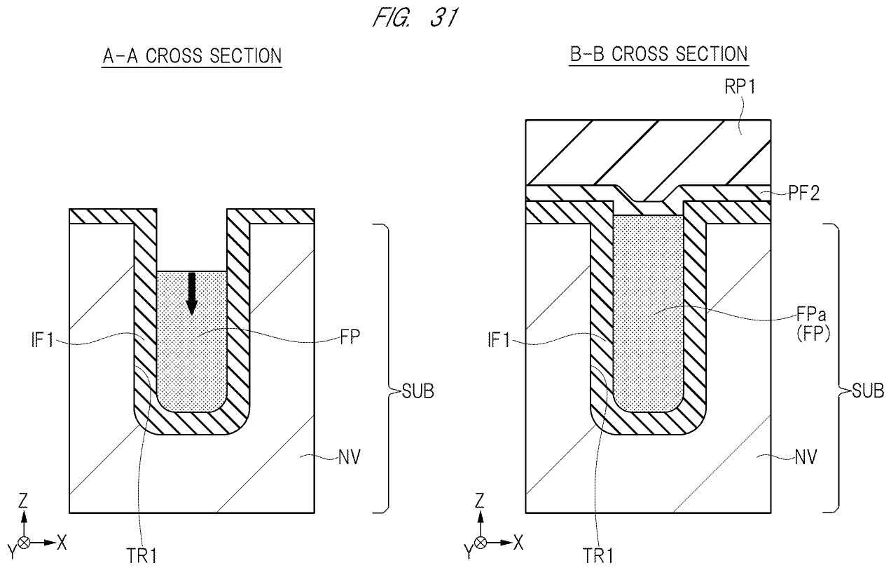

As illustrated in FIG. 31, first, the resist pattern RP1 selectively covering part of the field plate electrode FP to be the lead portion FPa is formed on the protective film PF2 as similar to the first embodiment. Next, an anisotropic etching process is performed while using the resist pattern RP1 as a mask to remove the protective film PF2 formed on another part of the field plate electrode FP.

Next, an etching process using, for example, SF₆ gas is performed to the field plate electrode FP while using the resist pattern RP1 as a mask. In this manner, another part of the field plate electrode FP is selectively recessed. A not-recessed part of the field plate electrode FP is to be the lead portion FPa. Then, the resist pattern RP1 is removed by an ashing process.

Note that the resist pattern RP1 may be removed after the protective film PF2 formed on another part of the field plate electrode FP is removed. In this case, an anisotropic etching process is performed to the field plate electrode FP under a condition making the protective film PF2 and the insulating film IF1 difficult to be etched and making the field plate electrode FP easy to be etched.

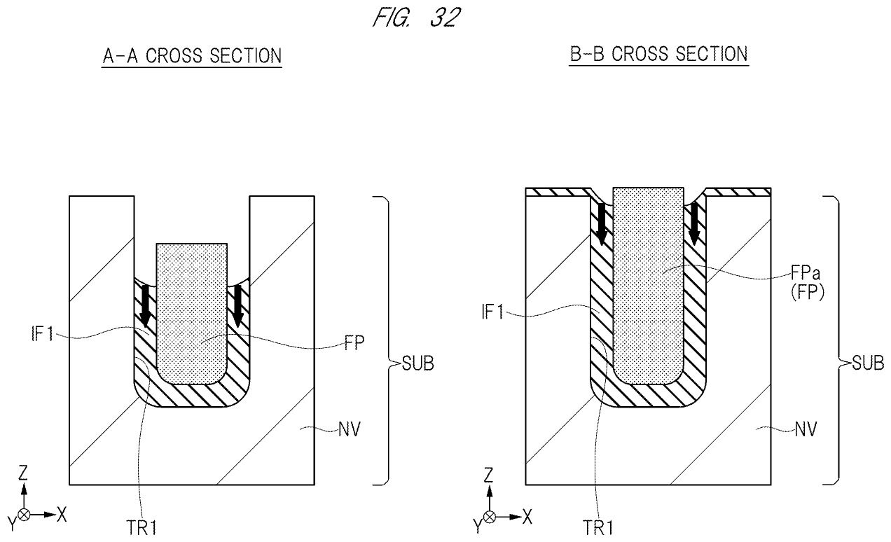

As illustrated in FIG. 32, an isotropic etching process using solution containing hydrofluoric acid is performed to the silicon oxide films (the protective film PF2 and the insulating film IF1). In this manner, the protective film PF2 formed on the lead portion FPa and the insulating film IF1 on the upper surface TS of the semiconductor substrate SUB are removed. At the same time, the insulating film IF1 inside the trench TR1 is recessed such that the upper surface of the insulating film IF1 is positioned lower than the upper surface of the field plate electrode FP.

In the B-B cross-section in FIG. 32, note that the case in which the insulating film IF1 is slightly left on the upper surface TS of the semiconductor substrate SUB has been exemplified. However, this insulating film IF1 may be completely removed to expose the upper surface TS of the semiconductor substrate SUB in the B-B cross section.

The protective film PF2 is formed on the lead portion FPa, and therefore, the recessed amount of the insulating film IF1 contacting with the lead portion FPa is smaller by the thickness of the protective film PF2 than that of the examined example of FIG. 50. Thus, the distance between the upper surface of the lead portion FPa and the upper surface of the insulating film IF1 is shorter than that of the examined example. The distance between the upper surface of the lead portion FPa and the upper surface of the insulating film IF1 is, for example, equal to or smaller than 100 nm.

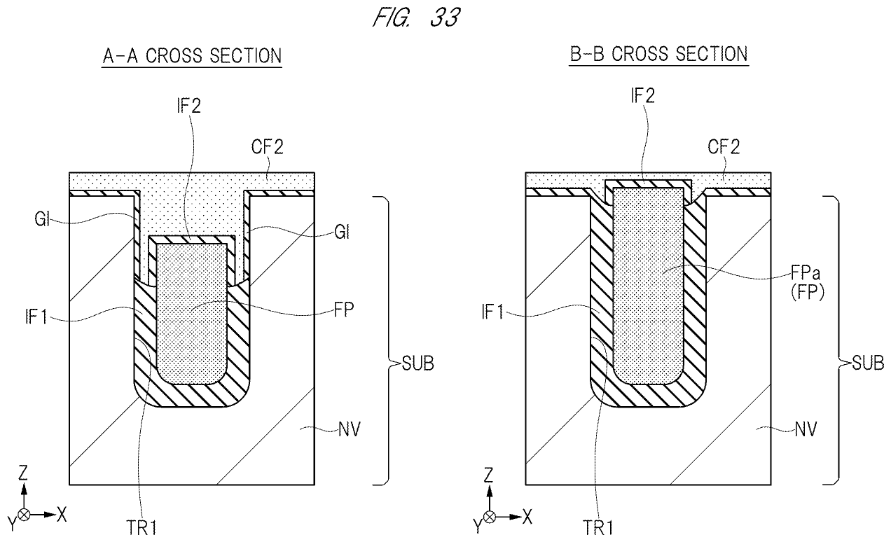

As illustrated in FIG. 33, the gate insulating film GI and the insulating film IF2 are formed by a similar method to that of the first embodiment. Next, the conductive film CF2 is formed on the gate insulating film GI, on the insulating film IF2, and on the insulating film IF1 so as to fill the inside of the trench TR1. Next, a polishing process using a CMP method is performed to the conductive film CF2.

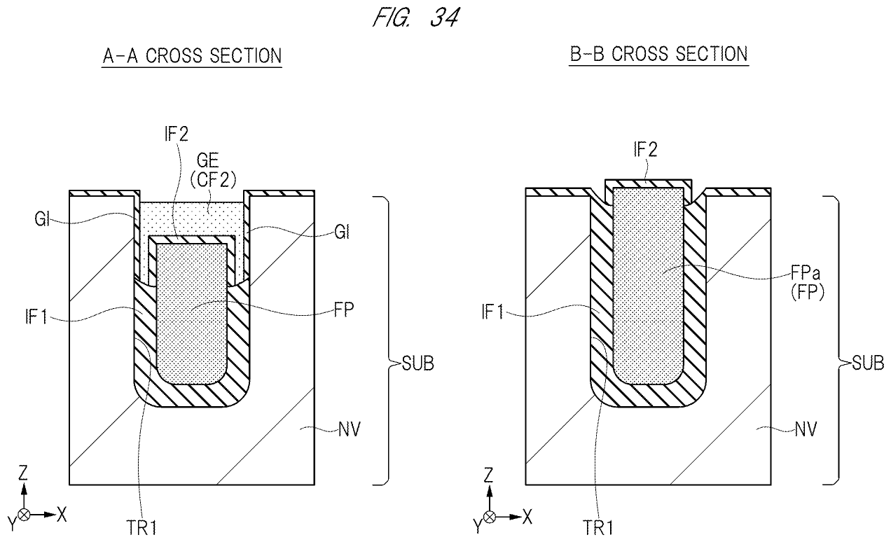

As illustrated in FIG. 34, an anisotropic etching process is performed to the conductive film CF2 to remove the conducive film CF2 formed outside the trench TR1. In this manner, the gate electrode GE is formed on the field plate electrode FP inside the trench TR1.

Subsequent manufacturing steps are similar to the manufacturing step of FIG. 17 and the continued steps in the first embodiment.

As described above, in the third embodiment, the distance between the upper surface of the lead portion FPa and the upper surface of the insulating film IF1 is shorter due to the formation of the protective film PF2. Thus, the conductive film CF2 formed on the insulating film IF1 and the insulating film IF2, which are in contact with the lead portion FPa, can be easily removed by the anisotropic etching process of FIG. 34. As described above, the formation of the residue RS as described in the examined example can be also suppressed by the technique of the third embodiment.

### Second Examined Example

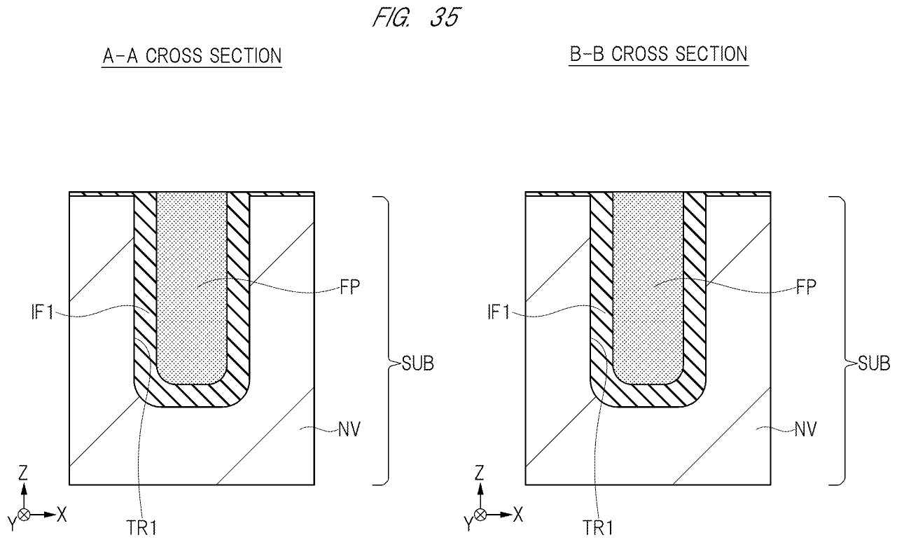

A semiconductor device 100 according to a second examined example of the third embodiment will be described below with reference to FIGS. 35 to 41.

In the second examined example, a planarizing process is performed to the field plate electrode FP and the insulating film IF1 on the upper surface TS of the semiconductor substrate SUB before forming the protective film PF2.

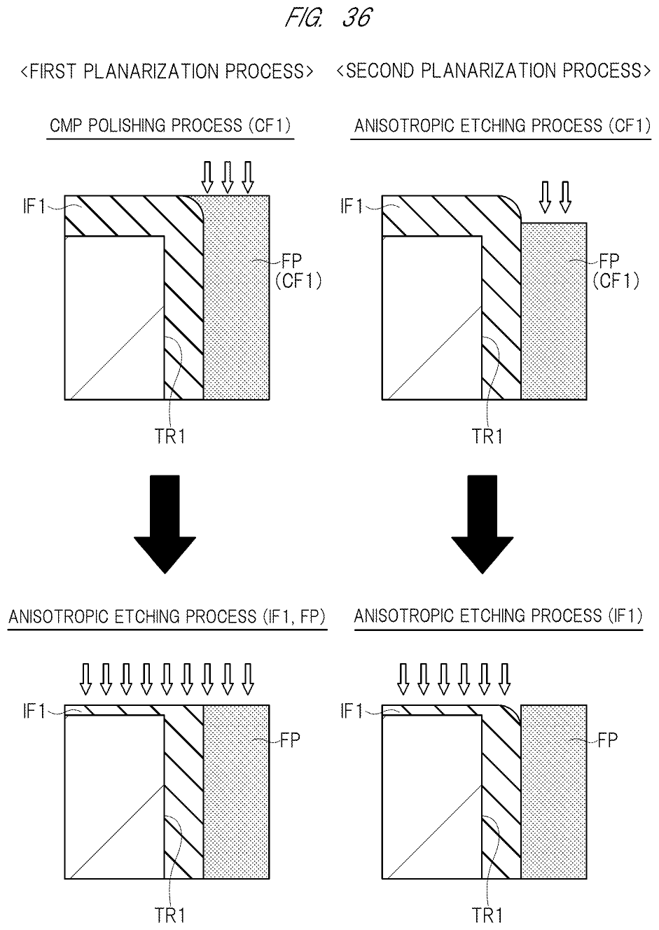

FIG. 35 illustrates a state in which the planarizing process is performed after the manufacturing step of FIG. 8. The planarizing process according to the second examined example includes, for example, two methods, and FIG. 36 illustrates the two methods in detail.

As illustrated in FIG. 36, in a “first planarizing process”, the field plate electrode FP is formed by a polishing process using a CMP method performed to the conductive film CF1. At this time, the insulating film IF1 on the upper surface TS of the semiconductor substrate SUB functions as an etching stopper. By this polishing process, the respective upper surfaces of the field plate electrode FP and the insulating film IF1 are planarized and even.

Next, an anisotropic etching process is performed to the insulating film IF1 on the upper surface TS of the semiconductor substrate SUB and to the field plate electrode FP. This anisotropic etching process is performed under a condition making both the insulating film IF and the field plate electrode FP easy to be scraped.

As illustrated in FIG. 36, in a “second planarizing process”, first, the field plate electrode FP is formed by a polishing process using a CMP method performed to the conductive film CF1. Next, an anisotropic etching process is performed to the field plate electrode FP such that the upper surface of the field plate electrode FP is positioned lower than the upper surface of the insulating film IF1 on the upper surface TS of the semiconductor substrate SUB.

Next, an anisotropic etching process is performed to the insulating film IF1 on the upper surface TS of the semiconductor substrate SUB. This anisotropic etching process is performed under a condition making the insulating film IF1 difficult to be etched and making the field plate electrode FP (conductive film CF1) easy to be etched.

In the “second planarizing g process,” a small gap is formed between the insulating film IF1 and the field plate electrode FP near the upper portion of the field plate electrode FP. However, this gap is filled with the protective film PF2 in the next step. Therefore, the respective upper surfaces of the field plate electrode FP and the insulating film IF1 are substantially planarized and even.

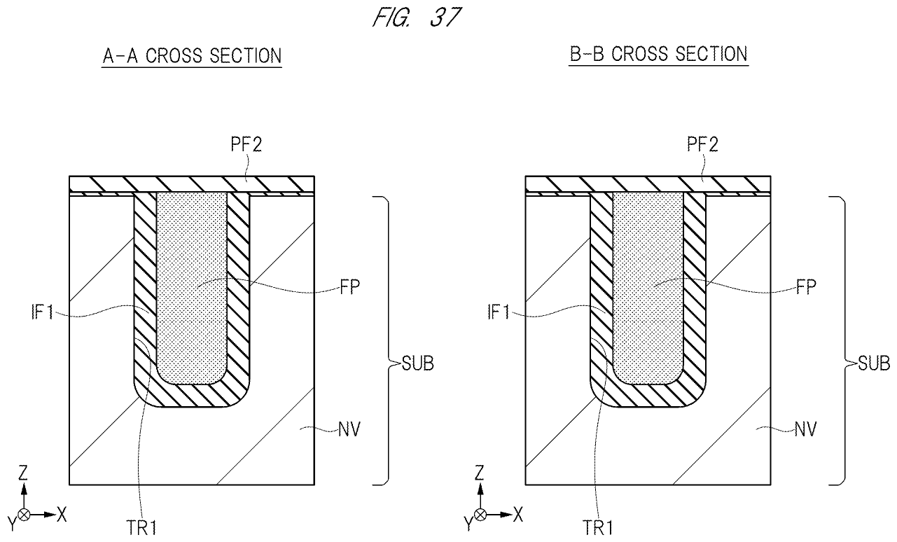

FIG. 37 illustrates a manufacturing step continued from FIG. 35 (FIG. 36). As illustrated in FIG. 37, the protective film PF2 is formed so as to cover the field plate electrode FP and the insulating film IF1 on the upper surface TS of the semiconductor substrate SUB by, for example, a CVD method.

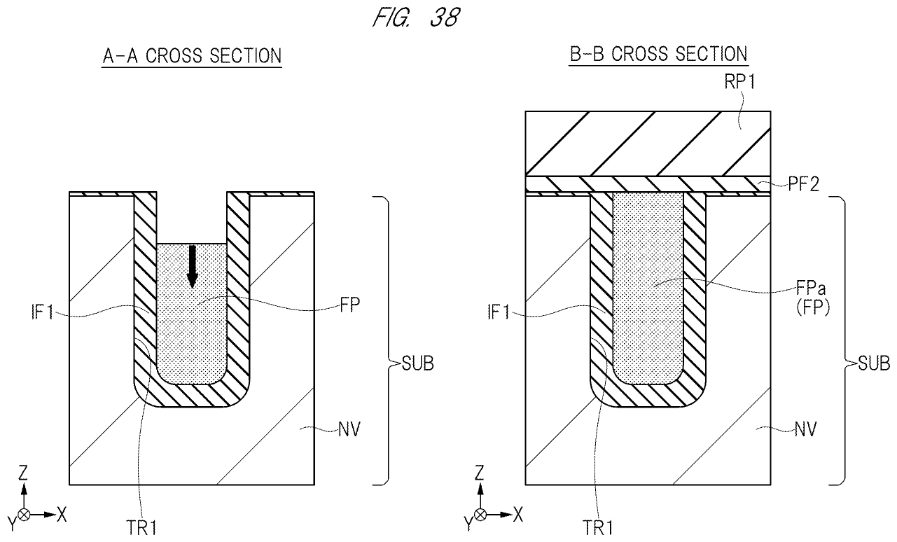

As illustrated in FIG. 38, first, the resist pattern RP1 is formed on the protective film PF2. Next, an anisotropic etching process is performed while using the resist pattern RP1 as a mask to remove the protective film PF2 formed on another part of the field plate electrode FP. Next, an anisotropic etching process is performed to the field plate electrode FP while using the resist pattern RP1 as a mask. In this manner, another part of the field plate electrode FP is selectively recessed. A not-recessed part of the field plate electrode FP is to be the lead portion FPa. Then, the resist pattern RP1 is removed by an ashing process.

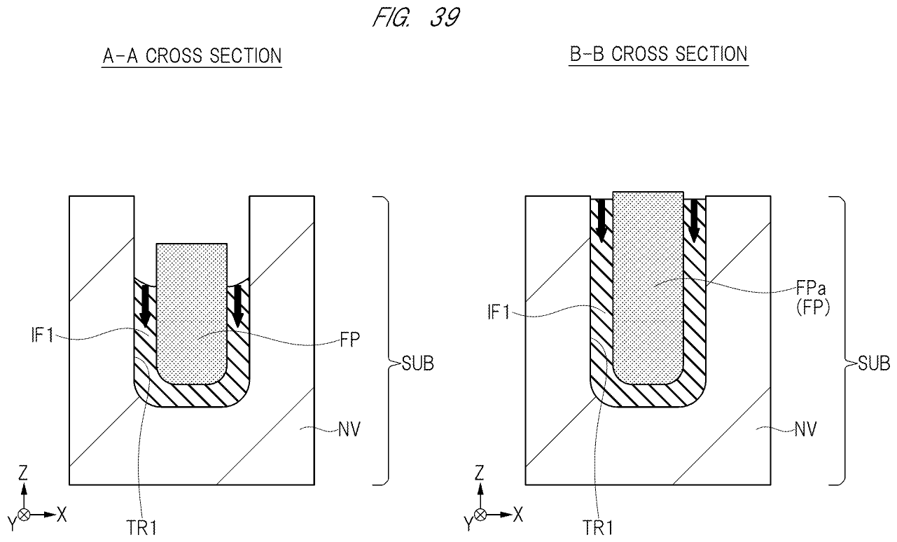

As illustrated in FIG. 39, an isotropic etching process using solution containing hydrofluoric acid is performed to the protective film PF2 and the insulating film IF1. In this manner, the protective film PF2 on the lead portion FPa and the insulating film IF1 on the upper surface TS of the semiconductor substrate SUB are removed. At the same time, the insulating film IF1 inside the trench TR1 is recessed such that the upper surface of the insulating film FI1 is positioned lower than the upper surface of the field plate electrode FP.

Also in the second examined example, a recessed amount of the insulating film IF1 contacting with the lead portion FPa is smaller by the thickness of the protective film PF2 than that of the examined example of FIG. 50. The distance between the upper surface of the lead portion FPa and the upper surface of the insulating film IF1 is, for example, equal to or smaller than 50 nm.

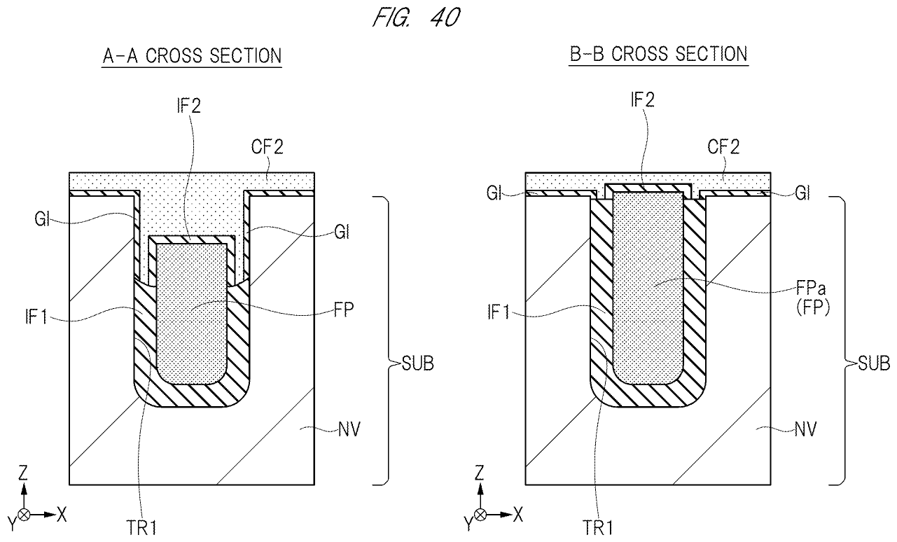

As illustrated in FIG. 40, the gate insulating film GI and the insulating film IF2 are formed. Next, the conductive film CF2 is formed on the gate insulating film GI, on the insulating film IF2, and on the insulating film IF1 so as to fill the inside of the trench TR1. Next, a polishing process using a CMP method is performed to the conductive film CF2.

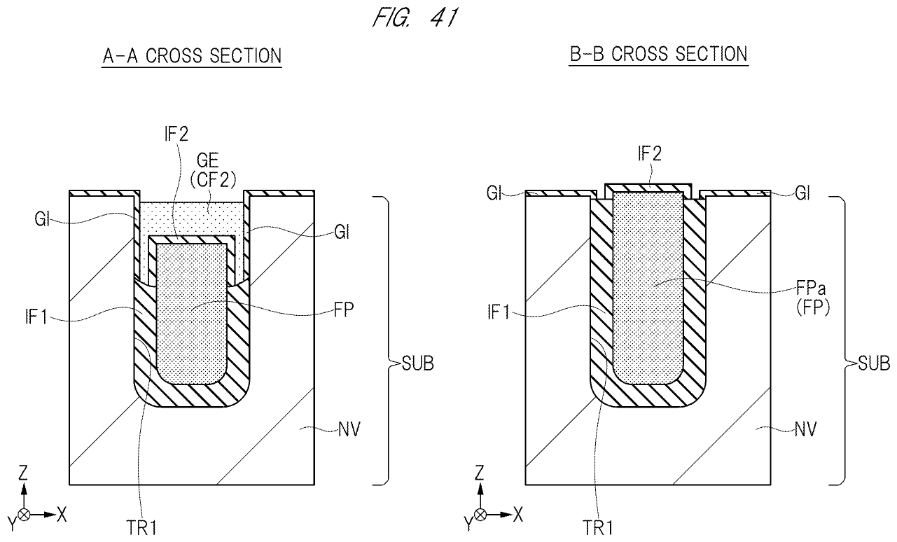

As illustrated in FIG. 41, by an anisotropic etching process to the conductive film CF2, the conductive film CF2 formed outside the trench TR1 is removed. In this manner, the gate electrode GE is formed on the field plate electrode FP inside the trench TR1.

The subsequent manufacturing steps are similar to the manufacturing step of FIG. 17 and the continued steps in the first embodiment.

As described above, also in the second examined example, the distance between the upper surface of the lead portion FPa and the upper surface of the insulating film IF1 is short due to the formation of the protective film PF2 as similar to the third embodiment. In the second examined example, due to the planarizing process, a gap is not formed between the insulating film IF1 and the field plate electrode FP near the upper portion of the field plate electrode FP.

Thus, as illustrated in the B-B cross section in FIG. 39, the upper surface of the insulating film IF1 is almost planarized after the insulating film IF1 is recessed by the isotropic etching process. Thus, the conductive film CF2 does not enter the gap when being formed. Therefore, at the time of the anisotropic etching process performed to the conductive film CF2, in the second examined example, the conductive film CF2 on the insulating film IF1 can be easier to be removed than that of the third embodiment, and therefore, the formation of the residue RS as described in the examined example can be further suppressed.

### Fourth Embodiment

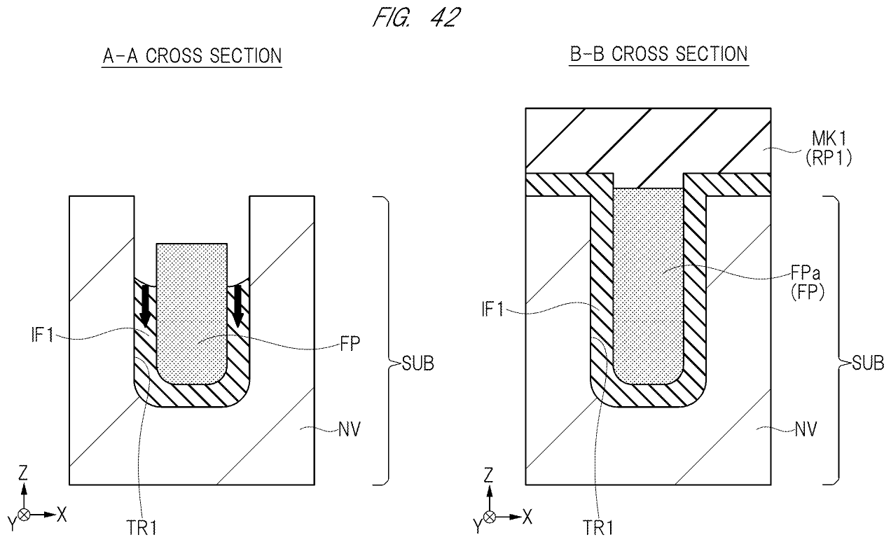

A semiconductor device 100 according to a fourth embodiment will be described below with reference to FIGS. 42 to 44. In the following explanation, note that differences from the first embodiment will be mainly described below, and the overlapping points with the first embodiment will not be described.

In the fourth embodiment, a step of recessing the field plate electrode FP and a step of recessing the insulating film IF1 are consecutively performed while using the same mask layer MK1 as a mask. Note that FIG. 42 illustrates a manufacturing step continued from FIG. 10 of the first embodiment.

As illustrated in FIG. 42, first, the resist pattern RP1 having been used to recess the field plate electrode FP in FIG. 10 is left as the mask layer MK1. Next, the insulating film IF1 on the upper surface TS of the semiconductor substrate SUB exposed from the mask layer MK1 is removed while using the mask layer MK1 as a mask. At the same time, the insulating film IF1 inside the trench TR1 is recessed such that the upper surface of the insulating film IF1 exposed from the mask layer MK1 is positioned lower than the upper surface of the field plate electrode FP. Then, the mask layer MK1 (resist pattern RP1) is removed by an ashing process.

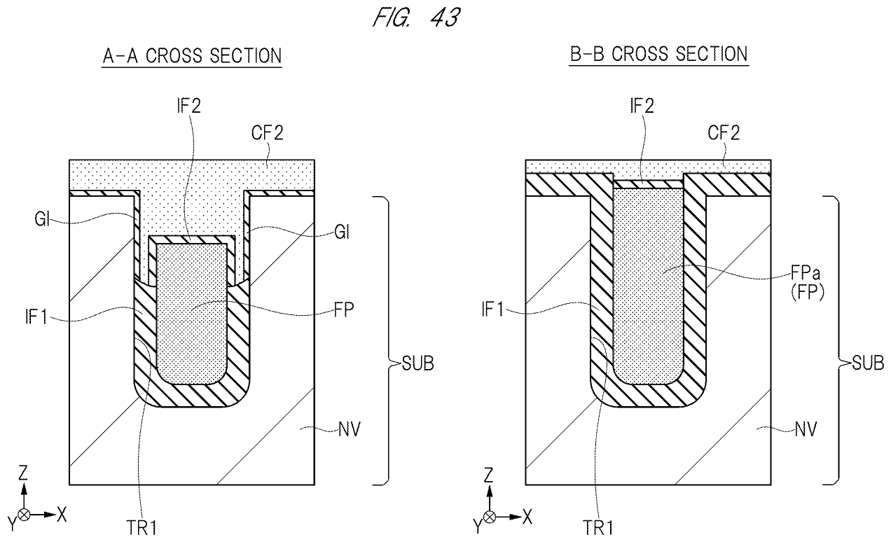

As illustrated in FIG. 43, the gate insulating film GI and the insulating film IF2 are formed. Next, the conductive film CF2 is formed on the gate insulating film GI, on the insulating film IF2, and on the insulating film IF1 so as to fill the inside of the trench TR1. Next, a polishing process using a CMP method is performed to the conductive film CF2.

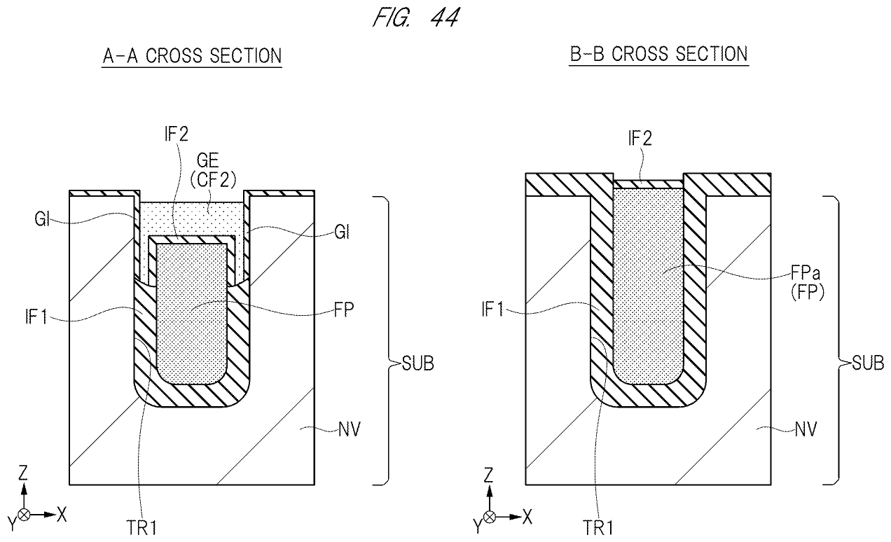

As illustrated in FIG. 44, an anisotropic etching process is performed to the conductive film CF2 to remove the conductive film CF2 formed outside the trench TR1. In this manner, the gate electrode GE is formed on the field plate electrode FP inside the trench TR1.

The subsequent manufacturing steps are similar to the manufacturing step of FIG. 17 and the continued steps in the first embodiment.

In the fourth embodiment, in the step of recessing the insulating film IF1, the insulating film IF1 contacting with the lead portion FPa is covered with the mask layer MK1 and is not recessed. Thus, the distance between the upper surface of the lead portion FPa and the upper surface of the insulating film IF1 is short. Therefore, the conductive film CF2 formed on the insulating film IF1 and on the insulating film IF2, which are in contact with the lead portion FPa, can be easily removed by the anisotropic etching process of FIG. 44. As described above, also by the technique of the fourth embodiment, the formation of the residue RS as described in the examined example can be suppressed.

### Third Examined Example

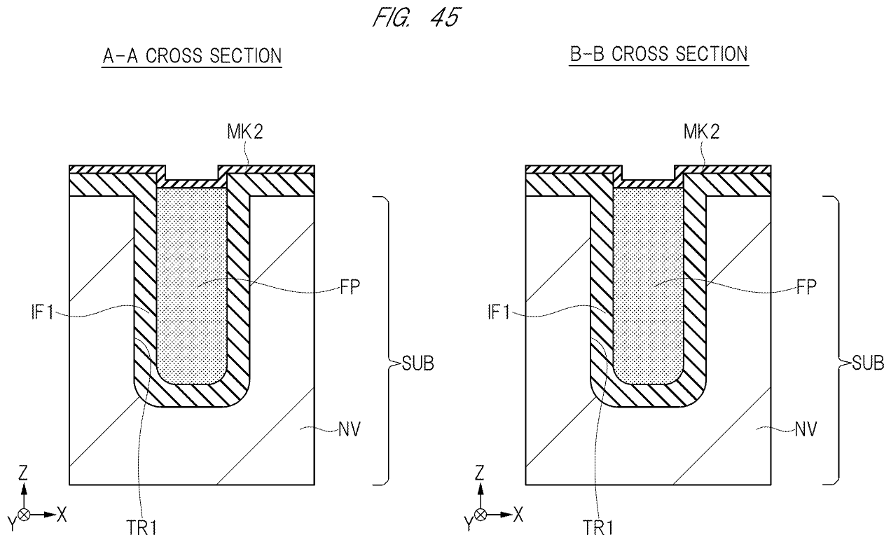

A semiconductor device 100 according to a third examined example of the fourth embodiment will be described below with reference to FIGS. 45 to 49.

In the third examined example, a step of recessing the field plate electrode FP and a step of recessing the insulating film IF1 are consecutively performed while using a mask layer MK2 different from the resist pattern RP1. Note that FIG. 45 illustrates a manufacturing step continued from FIG. 9 of the first embodiment.

As illustrated in FIG. 45, the mask layer MK2 is formed so as to cover the field plate electrode FP and the insulating film IF1 on the upper surface TS of the semiconductor substrate SUB by, for example, a CVD method. The mask layer MK2 is an insulating film made of a material such as a silicon nitride film different from the insulating film IF1, the insulating film IF2, the gate insulating film GI, the field plate electrode FP (conductive film CF1), and the gate electrode GE (conductive film CF2). A thickness of the mask layer MK2 is, for example, equal to or larger than 50 nm and equal to or smaller than 200 nm.

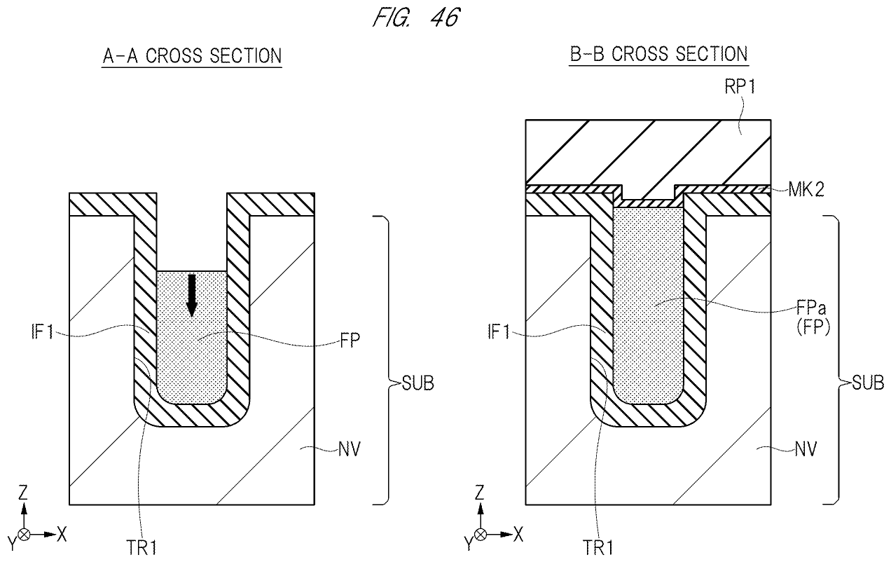

As illustrated in FIG. 46, first, the resist pattern RP1 similar to that of the first embodiment is formed on the mask layer MK2. Next, an anisotropic etching process is performed while using the resist pattern RP1 as a mask to pattern the mask layer MK2. The mask layer MK2 has an opening pattern corresponding to the opening pattern of the resist pattern RP1. That is, the mask layer MK2 has a pattern covering part of the field plate electrode FP and opening (exposing) another part of the field plate electrode FP.

Next, an etching process using, for example, SF₆ gas is performed to the field plate electrode FP while using the mask layer MK2 as a mask. In this manner, another part of the field plate electrode FP is selectively recessed. A not-recessed part of the field plate electrode FP is to be the lead portion FPa. Then, the resist pattern RP1 is removed by an ashing process.

Note that the resist pattern RP1 may be also used as a mask together with the mask layer MK2 during the anisotropic etching process. However, the resist pattern RP1 may be removed immediately after the mask layer MK2 is patterned. That is, the field plate electrode FP can be recessed while using only the mask layer MK2 as a mask.

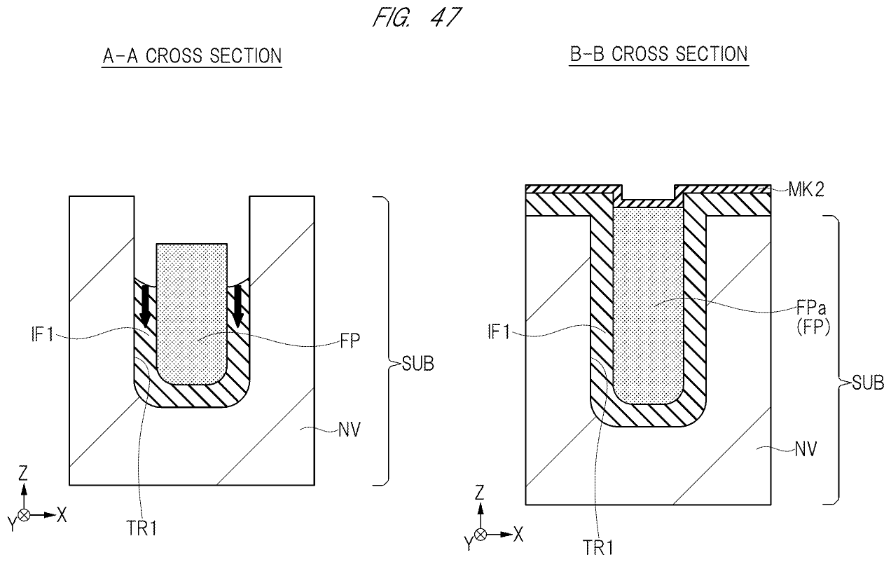

As illustrated in FIG. 47, the insulating film IF1 on the upper surface TS of the semiconductor substrate SUB exposed from the mask layer MK2 is removed while using the mask layer MK2 as a mask. At the same time, the insulating film IF1 inside the trench TR1 is recessed such that the upper surface of the insulating film IF1 exposed from the mask layer MK2 is positioned lower than the upper surface of the field plate electrode FP.

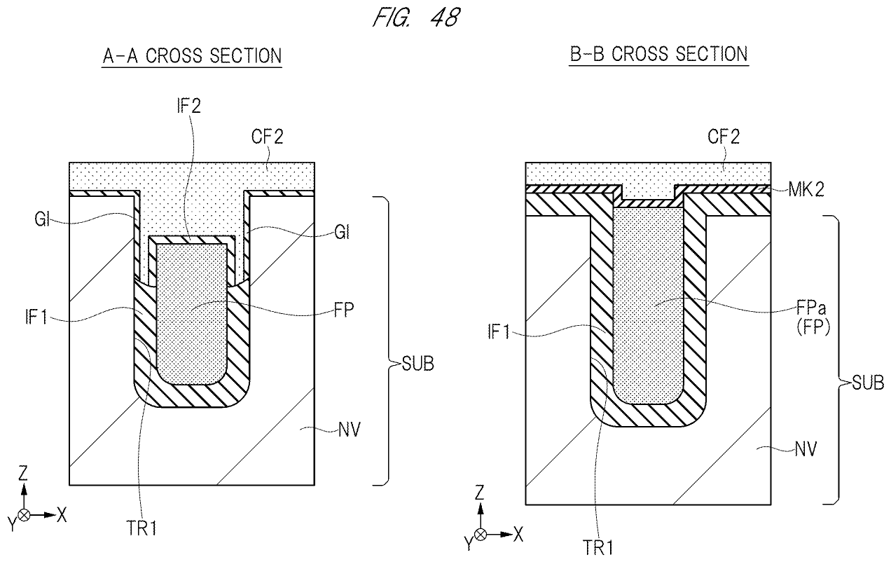

As illustrated in FIG. 48, the gate insulating film GI and the insulating film IF2 are formed. Since the upper surface of the lead portion FPa is covered with the mask layer MK2, the insulating film IF2 is not formed on the upper surface of the lead portion FPa. Next, the conductive film CF2 is formed on the gate insulating film GI, on the insulating film IF2, and on the insulating film IF1 so as to fill the inside of the trench TR1. Next, a polishing process using a CMP method is performed to the conductive film CF2.

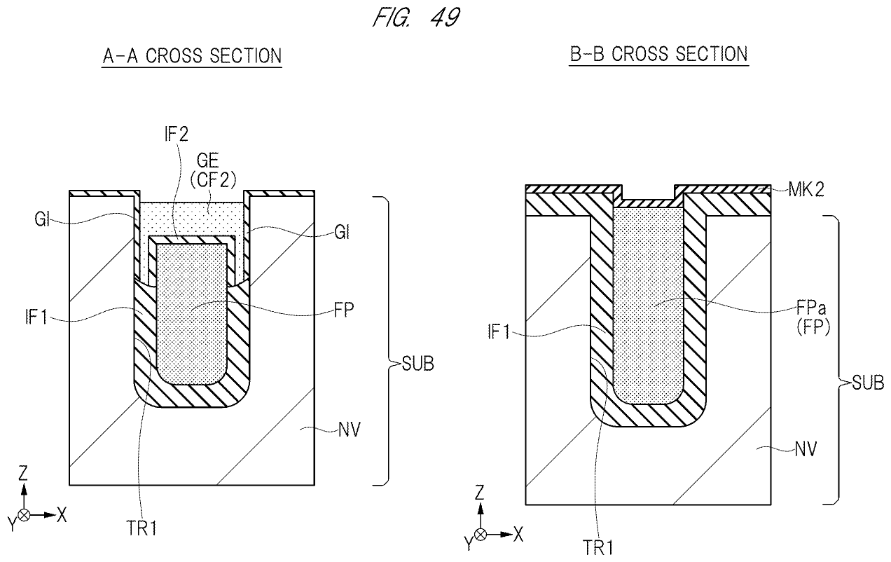

As illustrated in FIG. 49, an anisotropic etching process is performed to the conductive film CF2 to remove the conductive film CF2 formed outside the trench TR1. In this manner, the gate electrode GE is formed on the field plate electrode FP inside the trench TR1.

Then, the mask layer MK2 is removed by an anisotropic etching process or an isotropic etching process using solution containing phosphoric acid. Note that the mask layer MK2 may be removed immediately after the insulating film IF1 inside the trench TR1 of FIG. 47 is recessed.

The subsequent manufacturing steps are similar to the manufacturing step of FIG. 17 and the continued steps in the first embodiment.

In the third examined example, in the step of recessing the insulating film IF1, the insulating film IF1 contacting with the lead portion FPa is covered with the mask layer MK2 and is not recessed. Thus, the distance between the upper surface of the lead portion FPa and the upper surface of the insulating film IF1 is short. Therefore, the conductive film CF2 formed on the mask layer MK2 contacting with the lead portion FPa can be easily removed by the anisotropic etching process of FIG. 49. As described above, the formation of the residue RS as described in the examined example can be also suppressed by the technique of the third examined example.

In the foregoing, the present invention has been concretely described on the basis of the embodiments. However, the present invention is not limited to the foregoing embodiments, and various modifications can be made within the scope of the present invention.

Part of the contents described in the embodiments will be described below.

### [Statement 1]

A method of manufacturing a semiconductor device, including steps of:
(a) preparing a semiconductor substrate of a first conductive type, the semiconductor substrate having an upper surface and a lower surface;
(b) after the step of (a), forming a trench in the semiconductor substrate to have a predetermined depth from the upper surface of the semiconductor substrate;
(c) after the step of (b), forming a first insulating film on the upper surface of the semiconductor substrate and in an inside of the trench;
(d) after the step of (c), forming a first conductive film on the first insulating film so as to fill the inside of the trench;
(e) after the step of (d), forming, as a field plate electrode, the first conductive film left in the inside of the trench by removing the first conductive film located in an outside of the trench;
(f) after the step of (e), forming a first resist pattern, which has a pattern covering a part of the field plate electrode, and exposing another part of the field plate electrode, on the upper surface of the semiconductor substrate;
(g) after the step of (f), selectively recessing the another part of the field plate electrode by performing an anisotropic etching process while using the first resist pattern as a mask such that the part of the field plate electrode is left as a lead portion;
(h) after the step of (g), removing the first resist pattern;
(i) after the step of (h), removing the first insulating film located on the upper surface of the semiconductor substrate, and recessing the first insulating film located in the inside of the trench such that an upper surface of the first insulating film is positioned lower than an upper surface of the field plate electrode;
(j) after the step of (i), forming a gate insulating film in the inside of the trench located on the first insulating film, and forming a second insulating film so as to cover the field plate electrode exposed from the first insulating film;
(k) after the step of (j), forming a second conductive film on each of the gate insulating film, the second insulating film and the first insulating film so as to fill the inside of the trench;
(l) after the step of (k), forming, as a gate electrode, the second conductive film left in the inside of the trench, which is located at a portion over the field plate electrode, by removing the second conductive film located in the outside of the trench;
(m) after the step of (l), forming a second resist pattern which has a pattern selectively exposing the lead portion in the field plate electrode, on the upper surface of the semiconductor substrate; and
(n) after the step of (m), performing an anisotropic etching process while using the second resist pattern as a mask under a condition making the gate insulating film and the second insulating film difficult to be etched and making the second conductive film easy to be etched.

### [Statement 2]

A method of manufacturing a semiconductor device having a cell region in which a MOSFET is formed and an outer region surrounding the cell region in plan view, including steps of:
(a) preparing a semiconductor substrate of a first conductive type, the semiconductor substrate having an upper surface and a lower surface;
(b) after the step of (a), forming a first trench in the semiconductor substrate in the cell region, and forming a second trench in the semiconductor substrate in the outer region to have a predetermined depth from the upper surface of the semiconductor substrate;
(c) after the step of (b), forming a first insulating film on the upper surface of the semiconductor substrate, in an inside of the first trench and inside of the second trench;
(d) after the step of (c), forming a first conductive film on the first insulating film so as to fill the inside of the first trench and the inside of the second trench;
(e) after the step of (d), forming, as a first field plate electrode, the first conductive film left in the inside of the first trench, and forming as a second field plate electrode, the first conductive film left in the inside of the second trench by removing the first conductive film located in an outside of the first trench and outside of the second trench;
(f) after the step of (e), forming a first resist pattern which has a pattern covering part of the first field plate electrode and the second field plate electrode, and exposing another part of the field plate electrode, on the upper surface of the semiconductor substrate;
(g) after the step of (f), selectively recessing the another part of the first field plate electrode while using the first resist pattern as a mask such that the part of the first field plate electrode and the second field plate electrode are left as lead portions;
(h) after the step of (g), removing the first resist pattern;
(i) after the step of (h), removing the first insulating film located on the upper surface of the semiconductor substrate, and recessing the first insulating film located in the inside of the first trench and the inside of the second trench such that an upper surface of the first insulating film is positioned lower than an upper surface of the first field plate electrode and an upper surface of the second field plate electrode;
(j) after the step of (i), forming a gate insulating film in the inside of the first trench and the inside of the second trench on the first insulating film, and forming a second insulating film so as to cover the first field plate electrode exposed from the first insulating film and the second field plate electrode;
(k) after the step of (j), forming a second conductive film on each of the gate insulating film, the second insulating film and the first insulating film so as to fill the inside of the first trench and the inside of the second trench;
(l) after the step of (k), forming, as a gate electrode, the second conductive film left in the inside of the first trench, which is located at a portion over the first field plate electrode, by removing the second conductive film located in the outside of the first trench and the outside of the second trench;
(m) after the step of (l), forming a second resist pattern which has a pattern selectively exposing the second field plate electrode, on the upper surface of the semiconductor substrate; and
(n) after the step of (m), performing an anisotropic etching process while using the second resist pattern as a mask under a condition making the gate insulating film and the second insulating film difficult to be etched and making the second conductive film easy to be etched,
the first trench extends in a first direction in plan view,
the second trench extends in the first direction and a second direction orthogonal to the first direction in plan view to surround the cell region,
the gate electrode includes a first end portion in the first direction and a second end portion opposite to the first end portion in the first direction,
the lead portion of the first field plate electrode is formed in the inside of the first trench between the gate electrode at the first end portion side and the gate electrode at the second end portion side,
in the step of (l), a joint portion for connecting the gate electrode at the first end portion side and the gate electrode at the second end portion side is formed as a part of the gate electrode on a side surface of the lead portion of the first field plate electrode via the second insulating film,
in the step of (l), a residue of the second conductive film is formed on a side surface of the second field plate electrode via the second insulating film, and
the residue is removed in the step of (n).

### [Statement 3]

A semiconductor device having a cell region in which a MOSFET is formed and an outer region surrounding the cell region in plan view, including:
a semiconductor substrate of a first conductive type, the semiconductor substrate having an upper surface and a lower surface;
a first trench formed in the cell region in the semiconductor substrate to have a predetermined depth from the upper surface of the semiconductor substrate;
a second trench formed in the outer region in the semiconductor substrate to have a predetermined depth from the upper surface of the semiconductor substrate;
a first field plate electrode formed at a lower portion of the first trench located in an inside of the first trench;
a gate electrode formed at an upper portion of the first trench located in the inside of the first trench and electrically insulated from the first field plate electrode; and
a second field plate electrode formed in an inside of the second trench,
the first trench extends in a first direction in plan view,
the second trench extends in the first direction and a second direction orthogonal to the first direction in plan view to surround the cell region,
the gate electrode includes a first end portion in the first direction and a second end portion opposite to the first end portion in the first direction,
a part of the first field plate electrode is formed at not only a lower portion of the first trench but also an upper portion of the first trench in the inside of the first trench between the gate electrode at the first end portion side and the gate electrode at the second end portion side, and configures a lead portion of the first field plate electrode,
the lead portion is formed in the inside of the first trench between the gate electrode at the first end portion side and the gate electrode at the second end portion side,
a joint portion for connecting the gate electrode at the first end portion side and the gate electrode at the second end portion side is formed as a part of the gate electrode on a side surface of the lead portion via an insulating film, and
a conductive film configuring the gate electrode and the joint portion is removed on a side surface of the second field plate electrode.

What is claimed is:

1. A method of manufacturing a semiconductor device, comprising steps of:
(a) preparing a semiconductor substrate of a first conductive type, the semiconductor substrate having an upper surface and a lower surface;
(b) after the step of (a), forming a trench in the semiconductor substrate to have a predetermined depth from the upper surface of the semiconductor substrate toward the lower surface of the semiconductor substrate;
(c) after the step of (b), forming a first insulating film on the upper surface of the semiconductor substrate and in an inside of the trench;
(d) after the step of (c), forming a first conductive film on the first insulating film so as to fill the inside of the trench;
(e) after the step of (d), forming, as a field plate electrode, the first conductive film left in the inside of the trench by removing the first conductive film located in an outside of the trench;
(f) after the step of (e), selectively removing an another part of the field plate electrode such that a part of the field plate electrode is left as a lead portion;
(g) after the step of (f), removing the first insulating film located on the upper surface of the semiconductor substrate, and recessing the first insulating film located in the inside of the trench toward a bottom portion of the trench such that an upper surface of the first insulating film located in the inside of the trench is positioned lower than an upper surface of the field plate electrode in cross sectional view;
(h) after the step of (g), forming a first protective film on the upper surface of the semiconductor substrate and in the inside of the trench so as to cover the field plate electrode and the first insulating film;
(i) after the step of (h), removing the first protective film located on the upper surface of the semiconductor substrate, and recessing the first protective film located in the inside of the trench toward the bottom portion of the trench such that an upper surface of the first protective film located in the inside of the trench is positioned lower than the upper surface of the field plate electrode in cross sectional view;
(j) after the step of (i), forming a gate insulating film in the inside of the trench, which is located at a portion over the first protective film, and forming a second insulating film so as to cover the field plate electrode exposed from the first protective film;
(k) after the step of (j), forming a second conductive film on each of the gate insulating film, the second insulating film and the first protective film so as to fill the inside of the trench; and
(l) after the step of (k), forming, as a gate electrode, the second conductive film left in the inside of the trench, which is located at a portion over the field plate electrode, by removing the second conductive film located in the outside of the trench,
wherein the second conductive film formed on the first protective film and the second insulating film, which are in contact with the lead portion, in the step of (k) is removed in the step of (l).

2. The method of manufacturing the semiconductor device according to claim 1,
wherein each of the first insulating film and the first protective film is a silicon oxide film, and
the step of (g) and the step of (i) are performed by an isotropic etching process using solution containing hydrofluoric acid.

3. The method of manufacturing the semiconductor device according to claim 1,
wherein a thickness of the first protective film formed on the upper surface of the semiconductor substrate in the step of (h) is smaller than a thickness of the first insulating film formed on the upper surface of the semiconductor substrate in the step of (c).

4. The method of manufacturing the semiconductor device according to claim 1, further comprising steps of:
(m) after the step of (l), forming a third insulating film on the upper surface of the semiconductor substrate and on the gate electrode; and
(n) after the step of (m), removing the third insulating film and the gate insulating film in the outside of the trench.

5. The method of manufacturing the semiconductor device according to claim 4, further comprising steps of:
(o) after the step of (l) and before the step of (m), forming a resist pattern which has a pattern selectively opening the lead portion in the field plate electrode, on the upper surface of the semiconductor substrate; and
(p) after the step of (o) and before the step of (m), performing an etching process while using the resist pattern as a mask under a condition making the gate insulating film, the second insulating film, and the first protective film difficult to be etched and making the second conductive film easy to be etched.

6. A method of manufacturing a semiconductor device, comprising steps of:
(a) preparing a semiconductor substrate of a first conductive type, the semiconductor substrate having an upper surface and a lower surface;
(b) after the step of (a), forming a trench in the semiconductor substrate to have a predetermined depth from the upper surface of the semiconductor substrate;
(c) after the step of (b), forming a first insulating film on the upper surface of the semiconductor substrate and in an inside of the trench;
(d) after the step of (c), forming a first conductive film on the first insulating film so as to fill the inside of the trench;
(e) after the step of (d), forming, as a field plate electrode, the first conductive film left in the inside of the trench by removing the first conductive film located in an outside of the trench;
(f) after the step of (e), forming a second protective film so as to cover the field plate electrode and the first insulating film on the upper surface of the semiconductor substrate;
(g) after the step of (f), forming a first resist pattern, which has a pattern covering a part of the field plate electrode and exposing an another part of the field plate electrode, on the second protective film;
(h) after the step of (g), removing the second protective film formed on the another part of the field plate electrode by performing an anisotropic etching process while using the first resist pattern as a mask;
(i) after the step of (h), selectively recessing the another part of the field plate electrode such that the part of the field plate electrode is left as a lead portion by performing an etching process while using the first resist pattern as a mask;
(j) after the step of (i), removing the first resist pattern;
(k) after the step of (j), removing each of the second protective film formed on the lead portion and the first insulating film formed on the upper surface of the semiconductor substrate, and recessing the first insulating film located in the inside of the trench such that an upper surface of the first insulating film is positioned lower than an upper surface of the field plate electrode in cross sectional view;
(l) after the step of (k), forming a gate insulating film in the inside of the trench located on the first insulating film, and forming a second insulating film so as to cover the field plate electrode exposed from the first insulating film;
(m) after the step of (l), forming a second conductive film on the gate insulating film, the second insulating film, and the first insulating film so as to fill the inside of the trench; and
(n) after the step of (m), forming, as a gate electrode, the second conductive film left in the inside of the trench, which is located at a portion over the field plate electrode, by removing the second conductive film located in the outside of the trench,
wherein the second conductive film formed on the first insulating film and the second insulating film, which are in contact with the lead portion, in the step of (m) is removed in the step of (n).

7. The method of manufacturing the semiconductor device according to claim 6, further comprising a step of:
(o) before the step of (f), performing a planarizing process to the field plate electrode and the first insulating film on the upper surface of the semiconductor substrate.

8. The method of manufacturing the semiconductor device according to claim 7,
wherein the step of (o) further includes steps of:
(o1) in the step of (e), performing a polishing process using a CMP method to the first conductive film while using the first insulating film on the upper surface of the semiconductor substrate as an etching stopper; and
(o2) between the step of (o1) and the step of (f), performing an anisotropic etching process to the first insulating film on the upper surface of the semiconductor substrate and to the field plate electrode.

9. The method of manufacturing the semiconductor device according to claim 7,
wherein the step of (o) further includes steps of:
(o3) after the step of (e), performing an anisotropic etching process to the first conductive film such that an upper surface of the field plate electrode is positioned lower than an upper surface of the first insulating film on the upper surface of the semiconductor substrate; and
(o4) between the step of (o3) and the step of (f), preforming an anisotropic etching process to the first insulating film on the upper surface of the semiconductor substrate.

10. The method of manufacturing the semiconductor device according to claim 6,
wherein each of the first insulating film and the second protective film is a silicon oxide film, and
the step of (k) is performed by an isotropic etching process using solution containing hydrofluoric acid.

11. The method of manufacturing the semiconductor device according to claim 10,
wherein a thickness of the second protective film formed in the step of (f) is smaller than a thickness of a silicon oxide film etched by the isotropic etching process in the step of (k).

12. The method of manufacturing the semiconductor device according to claim 6, further comprising steps of:
(p) after the step of (n), forming a second resist pattern which has a pattern selectively opening the lead portion in the field plate electrode, on the upper surface of the semiconductor substrate; and
(q) after the step of (p), performing an etching process while using the second resist pattern as a mask under a condition making the gate insulating film and the second insulating film difficult to be etched and making the second conductive film easy to be etched.

13. A method of manufacturing a semiconductor device, comprising steps of:
(a) preparing a semiconductor substrate of a first conductive type, the semiconductor substrate having an upper surface and a lower surface;
(b) after the step of (a), forming a trench in the semiconductor substrate to have a predetermined depth from the upper surface of the semiconductor substrate;
(c) after the step of (b), forming a first insulating film on the upper surface of the semiconductor substrate and in an inside of the trench;
(d) after the step of (c), forming a first conductive film on the first insulating film so as to fill the inside of the trench;
(e) after the step of (d), forming, as a field plate electrode, the first conductive film left in the inside of the trench by removing the first conductive film located in an outside of the trench;
(f) after the step of (e), forming a mask layer, which has a pattern covering a part of the field plate electrode and exposing an another part of the field plate electrode, on the upper surface of the semiconductor substrate;
(g) after the step of (f), selectively recessing the another part of the field plate electrode while using the mask layer as a mask such that the part of the field plate electrode is left as a lead portion; and
(h) after the step of (g), removing the first insulating film located on the upper surface of the semiconductor substrate exposed from the mask layer, and recessing the first insulating film located in the inside of the trench such that an upper surface of the first insulating film exposed from the mask layer is positioned lower than an upper surface of the field plate electrode in cross sectional view while using the mask layer as a mask.

14. The method of manufacturing the semiconductor device according to claim 13, further comprising steps of:
(i) after the step of (h), removing the mask layer;
(j) after the step of (i), forming a gate insulating film in the inside of the trench on the first insulating film and forming a second insulating film so as to cover the field plate electrode exposed from the first insulating film;
(k) after the step of (j), forming a second conductive film on the gate insulating film, on the second insulating film, and on the first insulating film so as to fill the inside of the trench; and
(l) after the step of (k), forming, as a gate electrode, the second conductive film left in the inside of the trench, which is located at a portion over the field plate electrode, by removing the second conductive film located in the outside of the trench,
wherein the mask layer is a first resist pattern, and
the second conductive film formed on the first insulating film and on the second insulating film, which are in contact with the lead portion, in the step of (k) is removed in the step of (l).

15. The method of manufacturing the semiconductor device according to claim 14,
wherein the first insulating film is a silicon oxide film, and
the step of (h) is performed by an isotropic etching process using solution containing hydrofluoric acid.

16. The method of manufacturing the semiconductor device according to claim 14, further comprising steps of:
(m) after the step of (l), forming a second resist pattern which has a pattern selectively opening the lead portion in the field plate electrode, on the upper surface of the semiconductor substrate; and
(n) after the step of (m), performing an etching process while using the second resist pattern as a mask under a condition making the gate insulating film and the second insulating film difficult to be etched and making the second conductive film easy to be etched.

17. The method of manufacturing the semiconductor device according to claim 13, further comprising steps of:
(i) after the step of (h), forming a gate insulating film in the inside of the trench on the first insulating film and forming a second insulating film so as to cover the field plate electrode exposed from the first insulating film;
(j) after the step of (i), forming a second conductive film on the gate insulating film, on the second insulating film, on the first insulating film, and on the mask layer so as to fill the inside of the trench;
(k) after the step of (j), forming, as a gate electrode, the second conductive film left in the inside of the trench, which is located at a portion over the field plate electrode, by removing the second conductive film located in the outside of the trench; and
(l) after the step of (k), removing the mask layer,
wherein the mask layer is an insulating film made of a material different from the first insulating film, the second insulating film, the gate insulating film, the first conductive film, and the second conductive film, and
the second conductive film formed on the mask layer in contact with the lead portion in the step of (j) is removed in the step of (k).

18. The method of manufacturing the semiconductor device according to claim 17,
wherein the first insulating film is a silicon oxide film, and
the step of (h) is performed by an isotropic etching process using solution containing hydrofluoric acid.

19. The method of manufacturing the semiconductor device according to claim 17, further comprising steps of:
(m) between the step of (k) and the step of (l), forming a resist pattern which has a pattern selectively opening the lead portion in the field plate electrode, on the upper surface of the semiconductor substrate; and
(n) after the step of (m), performing an etching process while using the resist pattern as a mask under a condition making the gate insulating film, the second insulating film, and the mask layer difficult to be etched and making the second conductive film easy to be etched.
